(19) United States
(12) Patent Application Publication
(10) Pub. No.: US 2026/0129792 A1
(43) Pub. Date: May 7, 2026

(54) COLD PLATES IN COMPUTER HARDWARE

(71) Applicant: Nvidia Corporation, Santa Clara, CA (US)

(72) Inventors: Ryan Albright, Beaverton, OR (US); John Norton, Houston, TX (US); Ramanand Nayak, San Jose, CA (US); Mohammed Amin Godil, Vancouver, WA (US); Elad Mentovich, Tel Aviv (IL); Tahir Cader, Spokane Valley, WA (US)

(21) Appl. No.: 18/937,550

(22) Filed: Nov. 5, 2024

(51) Int. Cl. H05K 7/20

(52) U.S. Cl. CPC H05K 7/20254; H05K 7/20272; H05K 7/20281; H05K 7/20772

(57) ABSTRACT

Approaches presented herein provide for receiving liquid coolant from external sources to cold plates of a server or other liquid-cooled computer system. In at least one embodiment, initial standalone manifolds of the server can be forgone or bypassed, with the flow of liquid coolant received to a server at the cold plates. Some components of the server can be provided a source of cooling from the cold plates and other components can be provided the flow of liquid coolant distributed from the cold plates. The flow of liquid coolant can be provided from the cold plates to the some components to as a source of cooling, as well as to a separate manifold to be further distributed. The cold plates can be connected together to provide the appropriate flow of liquid coolant for the server.

### TECHNICAL FIELD

At least one embodiment pertains to cold plates in computer hardware.

### BACKGROUND

As the development of computer hardware systems continues, the complexity and power requirements of those systems increase. This increase in the complexity and power requirements can lead to constraints on available space and the ability to effectively cool the systems.

### BRIEF DESCRIPTION OF THE DRAWINGS

Various embodiments in accordance with the present disclosure will be described with reference to the drawings, in which:

FIGS. 1A-1C illustrate an exemplary data center cooling system subject to improvements described in at least one embodiment;

FIG. 2A illustrates server-level features associated with cold plates as liquid manifolds in computer hardware, according to at least one embodiment;

FIG. 2B illustrates a liquid-cooled server including server-level features associated with cold plates as liquid manifolds, according to at least one embodiment;

FIG. 3 illustrates rack-level features associated with cold plates as liquid manifolds in computer hardware, according to at least one embodiment;

FIG. 4 illustrates component-level features associated with cold plates as liquid manifolds in computer hardware, according to at least one embodiment;

FIGS. 5A-5B illustrate example cold plates to distribute liquid coolant in computer hardware, according to at least one embodiment;

FIG. 6 illustrates an example process that can be performed to use a cold plate as a manifold for a liquid cooled server, according to at least one embodiment;

FIG. 7 illustrates components of a distributed system that can be used to generate, test, and use data center cooling data, according to at least one embodiment;

FIG. 8 illustrates an example data center system, according to at least one embodiment;

FIG. 9 illustrates a distributed system, in accordance with at least one embodiment;

FIG. 10 illustrates a system that includes a client-server network, in accordance with at least one embodiment;

FIG. 11 illustrates a computer network connecting one or more computing machines, in accordance with at least one embodiment;

FIG. 12A illustrates a networked computer system, in accordance with at least one embodiment;

FIG. 12B illustrates a networked computer system, in accordance with at least one embodiment;

FIG. 12C illustrates a networked computer system, in accordance with at least one embodiment;

FIG. 13 illustrates a block diagram illustrating a computer system, according to at least one embodiment;

FIG. 14 illustrates a block diagram illustrating a computer system, according to at least one embodiment;

FIG. 15 illustrates a computer system, according to at least one embodiment;

FIG. 16 illustrates a computer system, according to at least one embodiment;

FIG. 17 illustrates exemplary integrated circuits and associated graphics processors, according to at least one embodiment;

FIGS. 18A and 18B illustrate exemplary integrated circuits and associated graphics processors, according to at least one embodiment;

FIG. 19 illustrates a computer system, according to at least one embodiment;

FIG. 20A illustrates a parallel processor, according to at least one embodiment;

FIG. 20B illustrates a partition unit, according to at least one embodiment; and

FIG. 21 illustrates at least portions of a graphics processor, according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

For liquid-cooled systems, such as a liquid-cooled server, an approach to provide cooling can include internal manifolds connected to a flow of cooling liquid. The manifold can use hoses and connectors to receive and distribute the cooling liquid to multiple components, including cold plates, within the server. As the amount of available space in a server continues to decrease, there are few such approaches to reduce or eliminate the need for the relatively thick hoses and expensive connectors typically used with standalone manifolds while still providing sufficient cooling capacity. Further, the standalone manifolds themselves take up valuable space and introduce additional connection points.

Approaches in accordance with various illustrative embodiments provide for using cold plates as liquid manifolds in computer hardware. In particular, at least one embodiment reduces costs, complexity, and overcrowding in liquid-cooled servers by receiving a flow of liquid coolant from an external coolant source to cold plates of the server for redistribution. A server can include compute devices positioned on circuit boards, cold plates to receive liquid coolant from an external coolant source, such as a cooling loop, and additional components able to receive a flow of liquid coolant. The cold plates can provide a source of cooling to the compute devices and can also provide the flow of liquid coolant to the additional components, such as other cold plates, manifolds, or cooling blocks. The server can receive the flow of liquid coolant from the external liquid coolant source to a first cold plates without an intervening manifold within the server housing. The cold plates can include inlets and outlets to connect with the external coolant source and the additional components to transfer the flow of liquid coolant. A surface of the cold plates can be used to provide the source of cooling to the compute devices.

The server in at least one embodiment can include cold plates able to be connected using a daisy chain-style connection including a plurality of hoses and connectors. Individual cold plates can be directly connected to multiple flows of liquid coolant, such as from a primary coolant loop and a secondary coolant loop. The cold plated can connect to the flow of liquid coolant using a manual connection or a blind mate connection. A server in at least one embodiment can include a manifold separate from the cold plates to provide a flow of liquid coolant to components on the circuit boards. The flow of liquid coolant in the liquid-cooled server can be monitored using flow rate sensors and/or leakage sensors, such as for per-route flow telemetry. For example, the sensor data can be passed to a data aggregator at a system level or a data center level. In an embodiment, the flow rate balancing of the flow of liquid coolant in the liquid-cooled server can be manually or programmatically achieved using flow dampers or controllers integral to the cold plate. For example, the flow dampers may be operated through external manual or automated end effectors. In an embodiment, the cold plate can limit backflow and crossflow between flow paths of the flow of liquid coolant to other components.

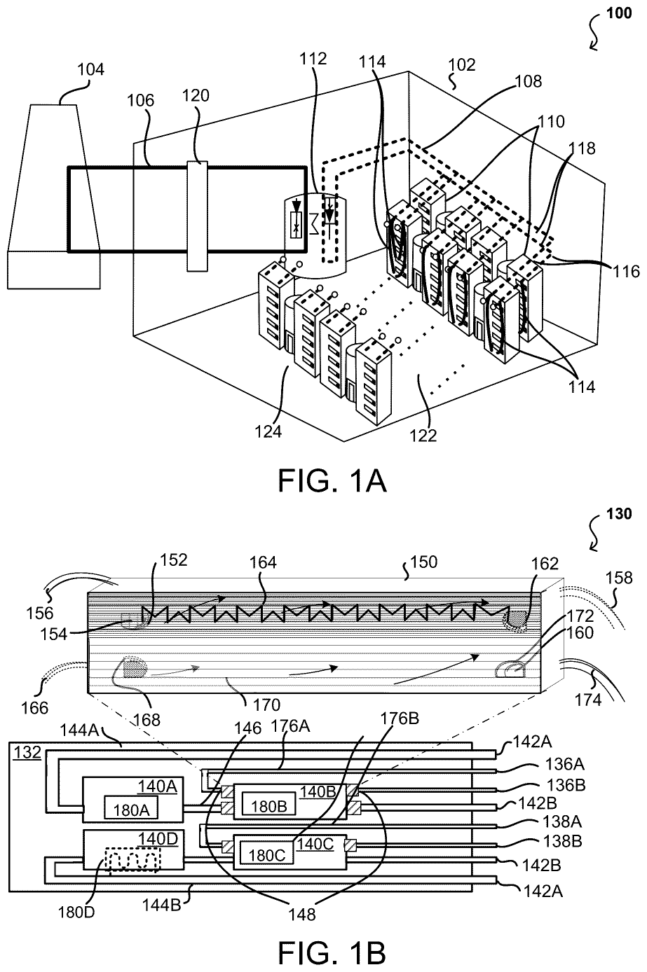

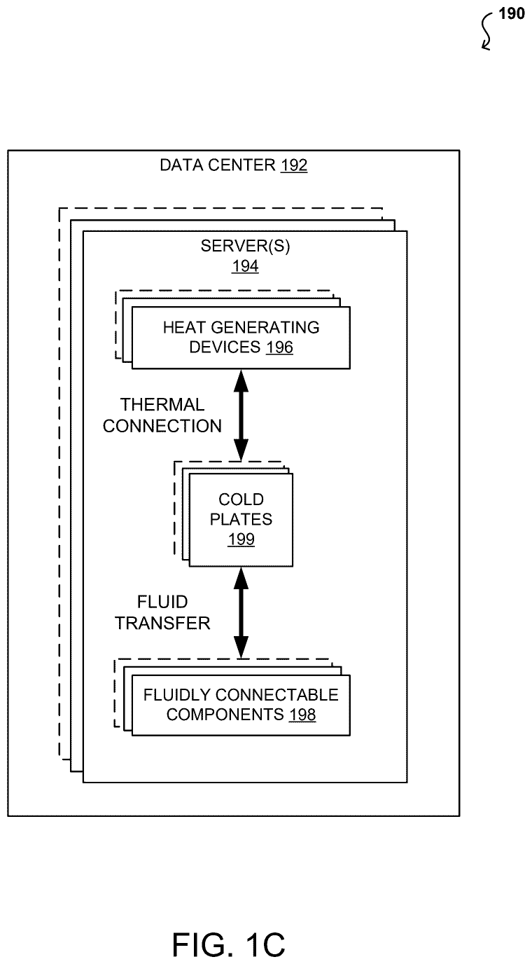

In at least one embodiment, an exemplary data center 100 can be utilized as illustrated in FIG. 1A, which has a cooling system subject to improvements described herein. In at least one embodiment, numerous specific details are set forth to provide a thorough understanding, but concepts herein may be practiced without one or more of these specific details. In at least one embodiment, data center cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a data center. In at least one embodiment, heat generated from these components, servers, and racks are cumulatively referred to as a heat feature or a cooling requirement as cooling requirement must address a heat feature entirely.

In at least one embodiment, a data center liquid cooling system is disclosed. In at least one embodiment, this data center cooling system addresses heat features in associated computing or data center devices, such as in graphics processing units (GPUs), in switches, in dual inline memory module (DIMMs), or central processing units (CPUs). In at least one embodiment, these components may be referred to herein as high heat density computing components. Furthermore, in at least one embodiment, an associated computing or data center device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

In at least one embodiment, an exemplary data center 100 can be utilized as illustrated in FIG. 1A, which has a cooling system subject to improvements described herein. In at least one embodiment, a data center 100 may be one or more rooms 102 having racks 110 and auxiliary equipment to house one or more servers on one or more server trays. In at least one embodiment, a data center 100 is supported by a cooling tower 104 located external to a data center 100. In at least one embodiment, a cooling tower 104 dissipates heat from within a data center 100 by acting on a primary cooling loop 106. In at least one embodiment, a cooling distribution unit (CDU) 112 is used between a primary cooling loop 106 and a second or secondary cooling loop 108 to enable extraction of heat from a second or secondary cooling loop 108 to a primary cooling loop 106. In at least one embodiment, a secondary cooling loop 108 can access various plumbing into a server tray as required, in an aspect. In at least one embodiment, loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 106, 108. In at least one embodiment, one or more coolant pumps may be used to maintain pressure differences within cooling loops 106, 108 to enable movement of coolant according to temperature sensors in various locations, including in a room, in one or more racks 110, and/or in server boxes or server trays within one or more racks 110.

In at least one embodiment, coolant in a primary cooling loop 106 and in a secondary cooling loop 108 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 110. In at least one embodiment, a CDU 112 is capable of sophisticated control of coolants, independently or concurrently, within provided cooling loops 106, 108. In at least one embodiment, a CDU may be adapted to control flow rate of coolant so that coolant is appropriately distributed to extract heat generated within associated racks 110. In at least one embodiment, more flexible tubing of rack manifold 114 is provided from a secondary cooling loop 108 to enter each server tray to provide coolant to electrical and/or computing components therein. In at least one embodiment, blind-mate fluid connectors may be used to at least partially remove a need for flex tubing. Further, the server trays herein can use flex tubing, hard piping, or a combination of the two.

In at least one embodiment, tubing room manifolds 118 that forms part of a secondary cooling loop 108 may include tubing for coolant. Separately, in at least one embodiment, row manifolds 116 may extend from room manifold 118 tubing and may also be part of a secondary cooling loop 108 but may include further tubing for coolant. In at least one embodiment, coolant tubing enters racks as part of a secondary cooling loop 108 but may be referred to as rack manifold 114 within one or more racks. In at least one embodiment, row manifolds 116 extend to all racks along a row in a data center 100. In at least one embodiment, plumbing of a secondary cooling loop 108, including room manifolds 118, row manifolds 116, and rack manifolds 114 may be improved by at least one embodiment herein. In at least one embodiment, a chiller 120 may be provided in a primary cooling loop within data center 100 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 110 may be transferred to a coolant exiting one or more racks 110 via flexible tubing of a rack manifold 114 of a second cooling loop 108. In at least one embodiment, second coolant (in a secondary cooling loop 108) from a CDU 112, for cooling provided racks 110, moves towards one or more racks 110 via provided tubing. In at least one embodiment, second coolant from a CDU 112 passes from on one side of a room manifold 118 having tubing, to one side of a rack 110 via a row manifold 116, and through one side of a server tray via different tubing of rack manifold 114. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 110 comes out of different side (such as exiting side) of tubing of rack manifold 114 and moves to a parallel, but also exiting side of a row manifold 116. In at least one embodiment, from a row manifold 116, spent second coolant moves in a parallel portion of a room manifold 118 and is going in an opposite direction than incoming second coolant (which may also be renewed second coolant), and towards a CDU 112.

In at least one embodiment, spent second coolant exchanges its heat with a primary coolant in a primary cooling loop 106 via a CDU 112. In at least one embodiment, spent second coolant may be renewed (such as relatively cooled when compared to a temperature at a spent second coolant stage) and ready to be cycled back to through a second cooling loop 108 to one or more computing components. In at least one embodiment, various flow and temperature control features in a CDU 112 enable control of heat exchanged from spent second coolant or flow of second coolant in and out of a CDU 112. In at least one embodiment, a CDU 112 may be also able to control a flow of primary coolant in primary cooling loop 106.

In at least one embodiment, exemplary server-level features 130 can be utilized as illustrated in FIG. 1B, which is associated with a cooling system subject to improvements described herein. In at least one embodiment, server-level features 130 as illustrated in FIG. 1B can be associated with cold plates as liquid manifolds. In at least one embodiment, server-level features 130 include a server tray or box 132. In at least one embodiment, a server tray or box 132 includes a server manifold 134 to be intermediately coupled between provided cold plates 140A-C of a server tray or box 132 and rack manifolds of a rack hosting a server tray or box 132. In at least one embodiment, a server tray or box 132 includes one or more cold plates 140A-C associated with one or more computing or data center components or devices 180A-C. In at least one embodiment, the one or more cold plates 140A-C may be intermediately coupled between an external coolant source, such as the rack manifolds of a rack hosting a server tray or box 132, and provided components of the server tray or box 132 or the rack. In at least one embodiment, one or more cold plates 140A-C may be dual-cooling-enabled cold plates having a first distinct path 164 capable of cooling using a first coolant and second a second distinct path 170 capable of cooling using a second coolant concurrently with a first coolant or at separate times. In at least one embodiment, such first distinct path 164 and second distinct path 170 are fins, tubes, or microchannels.

In at least one embodiment, at least one heat sink 140D includes fins and is exposed to an environment of a server tray or box 132 so that cold air from a cold aisle 122 can be used as cooling media through such fins to cool a heat sink 140D before such cold air exits to a hot aisle 124. In at least one embodiment, an associated computing device 180D benefits from cooling provided by such heat sink 140D (that need not have a cold plate or coolant for cooling). In at least one embodiment, therefore, cooling media may be air or single-phase fluid. In at least one embodiment, at least one thermal test vehicle (TTV) 180D is illustrated to indicate that testing of a data center cooling system may be performed using cold plates as liquid manifolds for data center cooling systems.

In at least one embodiment, one or more server-level cooling loops 144A, 144B may be provided between one or more cold plates 140A-C and an external source, such as rack manifolds, for single or dual-cooling-enabled cold plates. In at least one embodiment, each server-level cooling loop 144A, 144B includes an inlet line 142A and an outlet line 142B. In at least one embodiment, when there are series configured cold plates 140A, B, an intermediate line 146 may be provided. In at least one embodiment, however, for cold plates as liquid manifolds, distinct fluid paths, via provided lines 176A, may be established to pass a first coolant through first provided lines 136A, 136B and a second coolant through second provided lines 138A, 138B. In at least one embodiment, there may be separate server rack cooling manifolds for each type of coolant used.

In at least one embodiment, one or more cold plates 140A-C may be only single-coolant-enabled cold plates or only dual-coolant-enabled cold plates. In at least one embodiment, one or more cold plates 140A-C, when adapted for dual purpose, may support distinct ports and channels for a first secondary coolant of a secondary cooling loop and for a second secondary coolant (or local coolant) circulated from a local coolant source. In at least one embodiment, a first secondary coolant for cooling may be provided to one or more cold plates 140A-C via provided inlet and outlets 136A, 136B. In at least one embodiment, a second secondary coolant may be provided to one or more cold plates 140A-C via provided inlet and outlets 138A, 138B. In at least one embodiment, all such one or more cold plates, lines, or loops may be terminated using flow controllers having mechanical coupling and electrical coupling features. In at least one embodiment, electrical coupling features enable at least one processor to control aspects of a flow controller for cold plates as liquid manifolds.

In at least one embodiment, a server tray 132 is an immersive-cooled server tray that may be flooded by fluid. In at least one embodiment, a fluid for an immersive-cooled server tray may be a dielectric engineered fluid capable of being used in an immersive-cooled server. In at least one embodiment, a secondary coolant or local coolant may be used to cool engineered fluid. In at least one embodiment, a local coolant may be used to cool engineered fluid when a primary cooling loop associated with a secondary cooling loop circulating a secondary coolant has failed or is failing. In at least one embodiment, at least one cold plate therefore has ports for a secondary cooling loop and for a local coolant cooling loop from a local coolant source that is part of a system adapted for cold plates as liquid manifolds. In at least one embodiment, such a cold plate can support a local coolant that may be activated in an event of a failure in a primary cooling loop.

In at least one embodiment, at least one dual-cooling cold plate 140B, 150 may be configured to work alongside regular cold plates 140A, C. In at least one embodiment, a three-dimensional (3D) blow-up illustration (cold plate 150) provides internal detail of at least some features that may be included in a dual-cooling cold plate or a regular cold plate. In at least one embodiment, a tear-through of a cold plate 150 illustrates microchannels 170 and a distinct section for the first distinct path 164 as tubes functioning as heat dissipation features, as illustrated in FIG. 1A, B. In at least one embodiment, a distinct second section may be provided side-by-side and having heat dissipation features in at least a part of such a cold plate. In at least one embodiment, a local coolant-enabled cold plate may have only tubes as the first distinct path 164 and no microchannels as the second distinct path 170 therein.

In at least one embodiment, a dual-cooling cold plate 150 has distinct paths 164, 170 for secondary coolant of a secondary cooling loop, for local coolant of a local cooling loop, and for local coolant from a local coolant source. In at least one embodiment, in a use case of an immersive-cooled server, fluid that may be a dielectric engineered fluid may be adapted for both, a cold plate application and an immersive-cooled server tray application. In at least one embodiment, some microchannels 170 are paths provided by fins or other such aspects that raise internally and perpendicularly to a base of a cold plate section, and that have gaps therebetween for coolant or fluid flow. In at least one embodiment, some microchannels 170 are fluid pathways in a different cold plate section of a cold plate 150.

In at least one embodiment, reference to a cold plate, along with its dual-cooling features, may imply a reference to a cold plate that can support at least two types of cooling loops, unless otherwise stated. In at least one embodiment, both types of colds plates receive at least local coolant for cooling, but one type can support both, a secondary cooling loop or a local cooling loop and local coolant from a local coolant source. In at least one embodiment, a standard coolant, such as facility water may be used in a secondary cooling loop.

In at least one embodiment, a fluid or local coolant may only support cold plate usage and may not be available for immersive cooling. In at least one embodiment, each type of cold plate receives local coolant that may be associated with different secondary or local coolant from respective local cooling loops or other cooling loops interfacing with a primary cooling loop. In at least one embodiment, in situations where different fluids (such as secondary coolants and local coolants) are used in a data center cooling system, then a secondary or local cooling loop may be suited for a dual-cooling cold plate, along with local coolant. In at least one embodiment, secondary or local coolant may be supported by cold plates as liquid manifolds, so that different channels may be used for each of a local coolant and for different secondary coolants.

In at least one embodiment, a dual-cooling cold plate 150 is adapted to receive two types of fluids (such as a secondary coolant and a local coolant) and to keep two types of fluids distinct from each other via their distinct ports 152, 172, 168, 162 and their distinct paths 164, 170, such as by distinct sections separated by gaskets and plates (such as in a gasket type cold plate). In at least one embodiment, fluid lines 156, 158, 166, 174 are associated with such ports 152, 162, 168, 172, via respective flow controllers. In at least one embodiment, each distinct path is a cooling or flow path. In at least one embodiment, fluid (such as a local coolant or a secondary coolant) from a local coolant source and a secondary coolant may be provided simultaneously to address additional cooling requirements. In at least one embodiment, distinct ports and paths may support different sources that may be provided to address a higher cooling requirement from an associated computing device.

In at least one embodiment, a dual-cooling cold plate 150 includes ports 152, 262 to receive a local coolant into a cold plate 150, to enable such local coolant to pass through a cold plate 150, and to enable such local coolant to pass out of a cold plate 150. In at least one embodiment, a dual-cooling cold plate 150 includes ports 168, 172 to receive a secondary coolant into a cold plate 150, to enable such secondary coolant to pass through a cold plate 150, and to pass a secondary coolant out of a cold plate 150. In at least one embodiment, provided ports 152, 162 may have valve covers 154, 160 that may be directional to enable flow of local coolant or secondary coolant through a cold plate 150.

In at least one embodiment, provided valve covers 154 are mechanical features of associated flow controllers that also have corresponding electronic features (such as at least one processor to execute instructions stored in associated memory and to control mechanical features for associated flow controllers). In at least one embodiment, sensors can be used to provide feedback to adjust inlet local coolant through a cold plate.

In at least one embodiment, each valve may be actuated by an electronic feature of an associated flow controller. In at least one embodiment, electronic and mechanical features of provided flow controllers are integrated. In at least one embodiment, electronic and mechanical features of provided flow controllers are physically distinct. In at least one embodiment, reference to flow controllers may be to one or more of provided electronic and mechanical features or to their union but is at least in reference to features enabling control of flow of coolant or fluid through each cold plate or an immersion-cooled server tray or box.

In at least one embodiment, electronic features of provided flow controllers receive control signals and assert control over mechanical features. In at least one embodiment, electronic features of provided flow controllers may be actuators or other electronic parts of other similar electromechanical features. In at least one embodiment, flow pumps may be used as flow controllers. In at least one embodiment, impellers, pistons, or bellows may be mechanical features, and an electronic motor and circuitry form electronic features of provided flow controllers. In at least one embodiment, circuitry of provided flow controllers may include processors, memories, switches, sensors, and other components, altogether forming electronic features of provided flow controllers.

In at least one embodiment, provided ports 152, 162, 168, 172 of provided flow controllers are adapted to either allow entry or to allow egress of an immersive fluid. In at least one embodiment, flow controllers 148 may be associated with fluid lines 176A, 176B (also 156, 158) that enable entry and egress of a local coolant to a cold plate 140A-C. In at least one embodiment, other flow controllers may be similarly associated with coolant lines 142A, 146, 142B (also 166, 174) to enable entry and egress of a secondary coolant to a cold plate 140B, C.

In at least one embodiment, a local coolant enters provided fluid lines 176A, 176B via dedicated inlet and outlet lines 138A, 136B. In at least one embodiment, a cold plate 140A-D as a server manifold is adapted with channels therein to support distinct paths to distinct fluid lines 176A, 176B (also 156, 158) and to any remaining loops 144A, 144B that are associated with secondary coolant inlet and outlet lines 136A, 136B. In at least one embodiment, there may be multiple cold plates 140A-D as a server manifold to support local coolant and a distinct secondary coolant. In at least one embodiment, there may be multiple cold plates 140A-D as a server manifold to support entry and egress, distinctly, for each of a local coolant and of a secondary coolant. In at least one embodiment, a local coolant is singularly used without a secondary cooling loop.

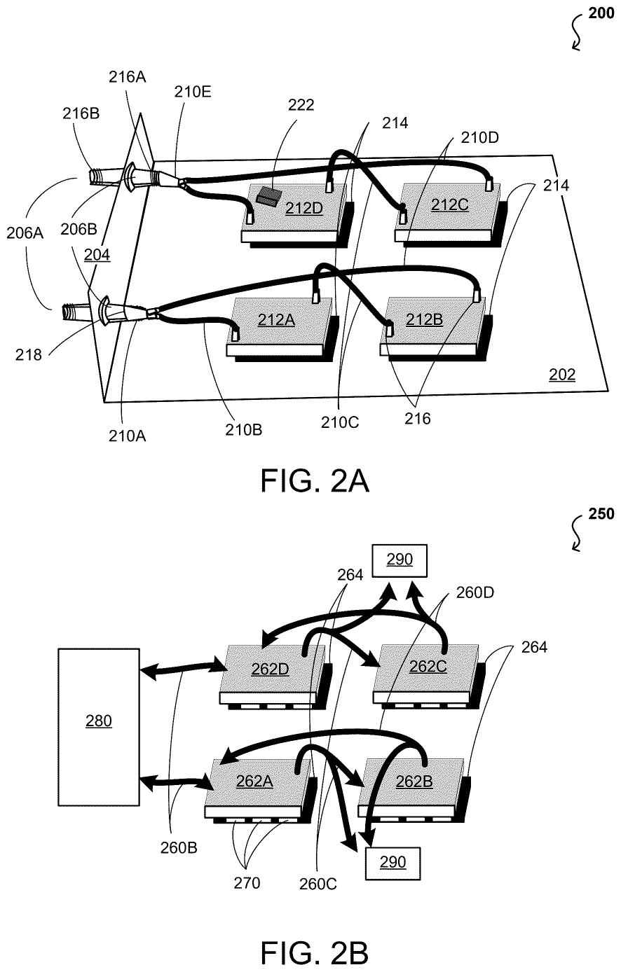

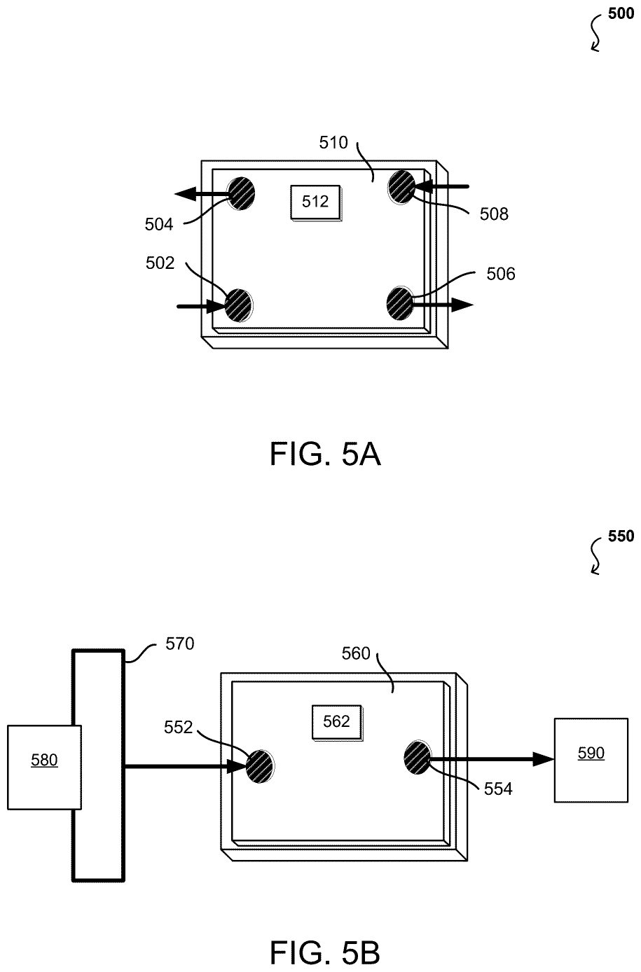

In at least one embodiment, an exemplary data center cooling system 190 can be utilized as illustrated in FIG. 1C, according to at least one embodiment. In at least one embodiment, a data center cooling system 190 includes a data center 192, such as the data center 100 as illustrated in FIG. 1A. The data center 192 may have a plurality of servers 194, such as including the server-level features 200 as illustrated in FIG. 2A or the server-level features 200 as illustrated in FIG. 2B. The individual servers 194 may have a plurality of heat generating devices 196, such as such as a circuit board, networking card, storage drive, compute block, processing unit, or other suitable devices. The individual servers 194 may include a plurality of fluidly connectable components 198, such as cold plates, manifolds, cooling blocks, or other suitable components. In an embodiment, the individual servers 194 may include at least one cold plate 199 as manifolds able to receive a flow of liquid coolant into the individual servers, such as the cold plate 500 as illustrated in FIG. 5A or the cold plate 550 as illustrated in FIG. 5B. The cold plates 199 as manifolds may be in thermal connection with one or more of the heat generating devices 196 of the individual servers 194, such as though a surface of the cold plates 199 as manifolds. The cold plates 199 as manifolds may be able to transfer the flow of cooling fluid with one or more of the fluidly connectable components 198 of the individual servers 194. The data center cooling system 190 may provide cooling by using the cold plates as manifolds 199 to a source of cooling to one or more of the heat generating devices 196 via the thermal connection and by using the cold plates 199 as manifolds to distribute the flow of cooling fluid to one or more of the fluidly connectable components 198 via fluid transfer.

FIG. 2A illustrates server-level features 200 associated with cold plates as liquid manifolds in computer hardware for data center cooling systems. In at least one embodiment, a data center cooling system, therefore, includes a server tray or box 202 having a surface 204 with one or more external flow controllers 206A and one or more internal flow controller 206B mounted removably thereon. In at least one embodiment, multiple flow controllers 206A, 206B may be provided so that entry of coolant occurs through one of such flow controllers and egress of coolant occurs through a different one of such flow controllers.

In at least one embodiment, each flow controller 206 includes an associated coupling 216A, 216B. In at least one embodiment, a sensor 222 can monitor a secondary coolant through a cold plate 212A, 212B, 212C, 212D. In at least one embodiment, such monitoring may be to a return temperature of a secondary coolant from one or more cold plates 212A, 212B, 212C, 212D. In at least one embodiment, such a sensor may be mounted on a rack manifold or a row manifold to sense a cumulative temperature of returned secondary coolant. In at least one embodiment, such a sensor may be able to determine pressure or flow rate of a return secondary coolant. In at least one embodiment, a sensor 222 may be also associated with a supply secondary coolant to provide reference or difference in temperature, pressure, or flow rate of a secondary coolant.

In at least one embodiment, one or more of a first flow controller 206A or a second flow controller 206B can change a flow of a secondary coolant through a flow controller 206A, 206B. In at least one embodiment, an associated coupling 216A, 216B includes push-coupling or threaded-coupling features to enable an external flow controller 218 to fluidly communicate with one or more of a first flow controller or a second flow controller. In at least one embodiment a sensor 222 may be adapted to monitor a flow volume of a secondary coolant that is to pass through a flow controller 206A, 206B.

In at least one embodiment, two flow controllers 206A, 206B may be adapted to close concurrently when a server tray or box 202 is to be disconnected from a rack. In at least one embodiment, two flow controllers 206A, 206B may be adapted to close separately depending on a local or a secondary coolant used, which allows for maintenance of a secondary cooling loop while a local cooling loop is operational to provide redundancy in operations. In at least one embodiment, this prevents leaks when removing a server tray or box from an external coupling, or prevents leaks when removing the cold plate 212A, 212B, 212C, 212D from the server tray or box 202. One or more leakage sensors may also be included, and may be associated with at least one of the server tray or box 202, the cold plate 212A, 212B, 212C, 212D, or other components.

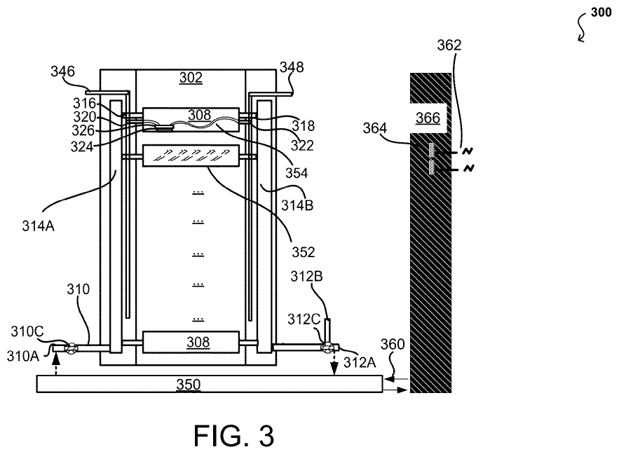

In at least one embodiment, secondary coolant enters a server tray or box 202 via a first flow controller 206A that may be coupled, at its associated coupling 216B, to a rack-side flow controller of a rack cooling manifold, as illustrated in FIG. 3, and then to the one or more cold plates 212A, 212B, 212C, 212D via a coolant inlet 210E. In at least one embodiment, secondary coolant flows through one or more flow controllers 206A, 206B. In at least one embodiment, FIG. 2A also illustrates an associated coupling 216A with a second flow controller 206B for coupling with a server-side flow controller. In at least one embodiment, one flow controller may be used for controlling a change in a flow or a pressure for a secondary coolant.

In at least one embodiment, as illustrated, valves covers that are actuated to different openness or closeness within a flow controller 206A, 206B enable a change in a flow rate or a flow volume of a secondary coolant there through. In at least one embodiment, impeller pumps that are controlled at different revolutions per minute (rpm) may be used to change this for a secondary coolant there through. In at least one embodiment, an impeller pump may be enabled to do this, but may require an associated valve cover in addition to an impeller. In at least one embodiment, a flow controller 206A, 206B may have a combination of a valve cover and an impeller flow controller representing two different flow controllers or a single flow controller depending on a configuration to perform different actions, including to stop or change a flow of a secondary coolant.

In at least one embodiment, secondary coolant flows through one or more flow controllers 206A, 206B, a coolant inlet 210A, and a cold plate 212A, 212B, 212C, 212D that may be an inlet server cooling manifold. In at least one embodiment, such a server cooling cold plate 212A, 212B, 212C, 212D as a manifold may be used so that multiple server-level cooling loops may be established without further flow controllers for each server-level cooling loop. In at least one embodiment, at least two distinct server-level cooling loops are illustrated in FIG. 2A. In at least one embodiment, secondary coolant enters a first cold plate 212A, from an external source via a coolant inlet 210B, to cool an associated computing device 214. In at least one embodiment, heat is removed from a such an associated computing device 214 by transfer to a secondary coolant.

In at least one embodiment, if serial cold plates are used in a server-level cooling loop, then an intermediate coolant inlet 210C enables flow of secondary coolant from a first cold plate 212A to a second cold plate 212B that is associated with a different computing device 214. In at least one embodiment, a coolant outlet 210D enables coolant to be passed back to cold plate 212A, 212B, 212C, 212D as a manifold that may act as an outlet server cooling manifold. In at least one embodiment, however, a single cooling cold plate 212A, 212B, 212C, 212D as a manifold having channels for inlet and for outlet may be used with one or more flow controllers 206. In at least one embodiment, each such coolant tube or line may be associated with a flow controller and/or a leak sensor so that leaks are prevented upon disconnection of any such coolant tube or line.

In at least one embodiment, secondary coolant then flows out from a server cooling cold plate 212A, 212B, 212C, 212D as a manifold through another flow controller 206 and to a rack outlet cooling manifold that is associated with a flow controller 206 at an outlet side via its own flow controllers. In at least one embodiment, one or more sensors 222 may be coupled to a processor that is external to such a flow controller 206A, 206B. In at least one embodiment, multiple sensors 222 communicate to an external processor that may be a part of a BMS or a building management system. In at least one embodiment, a control unit (such as a last server tray or box 308 of a rack 302 in FIG. 3) may be provided as a server tray or box form-factor within a rack to control all flow controllers within a rack.

In at least one embodiment, therefore, a processor may be adapted to receive input from a state sensor 222. In at least one embodiment, such input or sensor input may be about a flow controller 206A, 206B. In at least one embodiment, sensor input is as to temperature, flow rate, flow volume, or pressure associated with secondary coolant through one or more flow controllers 206A, 206B. In at least one embodiment, an action of a processor may be triggered based in part on such input from a sensor. In at least one embodiment, such an action may be an output from a processor to a primary flow controller, such as reference numeral 364 in FIG. 3. In at least one embodiment, a secondary coolant may be PG-25®, deionized water, and HC-30®.

FIG. 2B illustrates a liquid-cooled server 250 including server-level features associated with cold plates as liquid manifolds. In at least one embodiment, a liquid-cooled server 250 has components including at least one circuit board 264, one or more compute devices 270, and one or more cold plates 262A, 262B, 262C, 262D as manifolds. The compute devices 270 may be positioned on the circuit boards 264. In at least one embodiment, coolant from an external liquid coolant source 280 enters the liquid-cooled server 250 to the one or more cold plates 262A, 262B, 262C, 262D. The cold plates 262A, 262B, 262C, 262D as manifolds may be able to receive a flow of liquid coolant, such as from the external liquid coolant source 280. The cold plates 262A, 262B, 262C, 262D may then provide a source of cooling and distribute the flow of liquid coolant, such as to additional components 290 of the liquid-cooled server 250.

In at least one embodiment, a flow of liquid coolant 260B is received into a cold plate 262A, 262B, 262C, 262D that may be an inlet server cooling manifold. In at least one embodiment, at least two distinct server-level cooling loops are illustrated in FIG. 2B. In at least one embodiment, the flow of liquid coolant 260B may enter into the first cold plates 262A, 262D from the external liquid coolant source 280, to provide a source of cooling to the compute devices 270 on circuit board 264. An intermediate flow of liquid coolant 260C may enter into the second cold plates 262B, 262C to provide a source of cooling to the compute devices 270 on circuit board 264. In at least one embodiment, heat is removed from the compute devices 270 by transfer to a flow of liquid coolant through a surface of the cold plate 262A, 262B, 262C, 262Ds between the compute devices 270 and the a flow of liquid coolant. The compute devices 270 may also be positioned on an exterior thermal transfer surface of the one or more cold plates 262A, 262B, 262C, 262D separated from the flow of liquid coolant, in contact with an exterior thermal transfer surface of the one or more cold plates 262A, 262B, 262C, 262D separated from the flow of liquid coolant, or otherwise in thermal connection with the one or more cold plates 262A, 262B, 262C, 262D and also out of contact with a flow of liquid coolant.

In at least one embodiment, such as if serial cold plates are used in a server-level cooling loop, then the intermediate flow of liquid coolant 260C is provided from a first cold plate 262A, 262D to a second cold plate 262B, 262C that is associated with a different compute device 270, and may also be provided to additional components 290 of the liquid-cooled server 250. In at least one embodiment, a return flow of liquid coolant 260D may be sent back from the cold plate 262B, 262C to the cold plate 262A, 262D as a manifold that may act as an outlet server cooling manifold, such as to external liquid coolant source 280, and may also be provided to additional components 290 of the liquid-cooled server 250. In at least one embodiment, however, a single cooling cold plate 262A, 262B, 262C, 262D as a manifold having channels for inlet and for outlet may be used. In at least one embodiment, coolant may then flow out from a server cooling cold plate as a manifold and be removed from the server, such as to a rack outlet cooling manifold at an outlet side as the external liquid coolant source 280.

FIG. 3 illustrates rack-level features 300 associated with using cold plates as liquid manifolds in computer hardware for data center cooling systems. In at least one embodiment, such rack-level features 300 include one or more racks 302 in one or more rows. In at least one embodiment, each row may be associated with its own cooling manifold 350 that is associated with a secondary coolant for dual purpose cold plates, although only a secondary coolant-based cooling or only a local coolant-based cooling may be enabled for one or all of such racks 302 in FIG. 3 using dedicated cooling manifolds 346, 348.

In at least one embodiment, some server trays or boxes 308 may be associated with secondary coolant-based cooling, while other server tray or boxes may be associated with a local coolant-based cooling and some others may be associated with two-phase cooling. In at least one embodiment, in each such cases, server trays or boxes 308 are associated with a CDU 366 via lines 362, where such a CDU 366 supports using cold plates as liquid manifolds in computer hardware. In an embodiment, coolant may flow 360 between the CDU 366 and a coolant source via lines 362 using primary flow controllers 364.

In at least one embodiment, flow paths may be enabled to a dual-purpose cold plate 326, through one or more rack cooling manifolds 314A, 314B or 346, 348 that is within a rack 302. In at least one embodiment, a singular rack cooling manifold may support entry and egress of a secondary coolant and a separate rack cooling manifold may support entry and egress of a local coolant. In at least one embodiment, however, separate rack cooling manifolds 314A, 314B may be used for each of entry and of exit of each of such secondary coolant and local coolant depending on if both are used or if each is used independently.

In at least one embodiment, such a dual-purpose cold plate 326, which may act as a manifold, is associated with a computing device 324 that may have a cooling requirement may be addressed by a secondary coolant, a local coolant, or a combination of coolants. In at least one embodiment, such a flow path allows secondary or local coolant from a row cooling manifold 350 to enter into and exit from one or more rack cooling manifolds 314A, 314B. In at least one embodiment, secondary or local coolant may flow 360 between a row cooling manifold 350 and the CDU 366. In at least one embodiment, such secondary coolant flows through a row cooling manifold 350, through an inlet 310A of a rack 302, through a flow controller 310C adapted to switch between at least two coolant paths (or a coolant path and a local coolant path), through an inlet 310, and into a rack cooling manifold 314A. In at least one embodiment, such secondary or local coolant enters a cold plate 326 and addresses one cooling requirement associated with a cold plate 326 and/or its associated computing device 324. In at least one embodiment, a separate flow controller than an illustrated flow controller 310C may be used for local coolant.

In at least one embodiment, secondary or local coolant flows through a further inlet 316 of a server tray or box 308, to a cold plate 326 of an associated computing device 324, out of an outlet 318 of a server tray or box 308, through a rack cooling manifold 314B, into a further outlet 312, through another flow controller 312C, and out of an outlet line 312A to a row cooling manifold 350 that may be a same or a different row cooling manifold than an inlet side row cooling manifold. Further, a row cooling manifold 350 or a rack cooling manifold 314A, 314B may have different channels therein to support inlet and outlet flows.

In at least one embodiment, for a dual cooling cold plate or a single coolant cold plate, a local coolant may be caused to occur via different flow paths, such as an inlet or inlet lines from a distinct inlet manifold 346 provided at a top of a rack 302, through a channel of a rack cooling manifold 314A or a dedicated local coolant manifold 346, through direct lines 320, 354, 322 to a cold plate 326, and out of outlet lines of a further distinct manifold 348 at a top of a rack 302.

In at least one embodiment, a rack 302 can therefore include distinct local coolant flow paths than secondary coolant flow paths. In at least one embodiment, such direct lines may be available within each of a server trays or boxes 308 of a rack 302 and may also be available within an immersive server 352 of a rack 302. In at least one embodiment, such local coolant enters a cold plate 326 and addresses a second cooling requirement that may be associated with a cold plate 326 and/or its associated computing device 324. In at least one embodiment, a cold plate 326 is either a coolant cold plate, a local coolant cold plate, or a dual cooling cold plate supporting secondary coolant and local coolant, with a cold plate as a manifold.

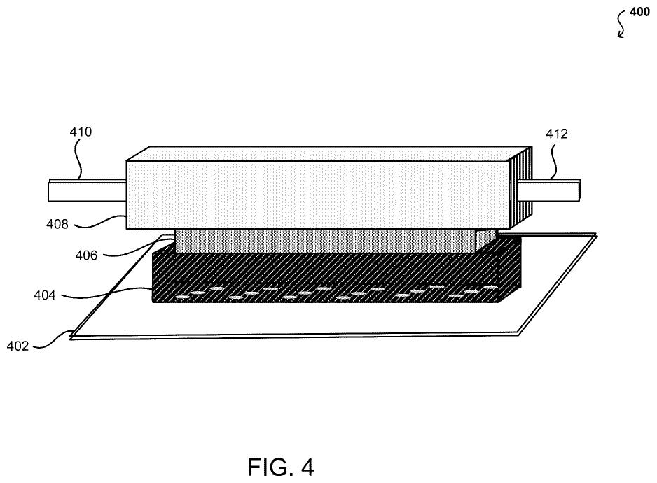

FIG. 4 illustrates component-level features 400 associated with cold plates as liquid manifolds in computer hardware for a data center liquid cooling system, according to at least one embodiment. The component-level features 400 include a computing or data center device formed of one or more of components 402, 404. In at least one embodiment, component 402 is a board or card, such as a printed circuit board (PCB) or printed circuit card that in enveloped and shielded to protect components therein. The PCB may hold at least one compute device. The compute device may comprise hardware, such as an application specific integrated circuit (ASIC). Other non-limiting examples of the compute device include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the compute device. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

In at least one embodiment, component 404 is a compute device such as a chip or semiconductor device, such as a CPU, a GPU, or a switch. In at least one embodiment, even though only one component 404 is illustrated, the PCB 402 may have multiple components mounted thereon. In at least one embodiment, the component 404 may include multiple die (such as a multi-core processor device). In at least one embodiment, the cores may be stacked or distributed. In at least one embodiment, the components 402, 404 may have different heat generating features represented by at least locations of the die therein. In the case of the PCB 402, when there are multiple components 404 thereon, each component may be a heat generating feature.

In at least one embodiment, a cold plate 408 as a manifold is associated with the computer device. In the illustration of FIG. 4, the cold plate 408 is associate with the computing device 404. In at least one embodiment, the cold plate 408 may extend throughout the dimensions of the PCB 402 to provide direct or indirect contact cooling to one or more computing components on the PCB 402. In at least one embodiment, when a graphics processing card is the computing device, the cold plate 408 extends over the entire card, but the channels therein may enable concentration of coolant or the flow of coolant over areas of the card having processor or memory-intensive computing devices. The computing device may therefore have further computing devices associated therewith.

In at least one embodiment, the cold plate 408 is associated with the computing device 404 via a thermal transfer layer 406. The thermal transfer layer may be a layer having one or more of silicon, a thermal interface material, or air. In at least one embodiment, there may be no thermal transfer layer 406 and the cold plate 408 may be directly associated with the computing device 404. The cold plate 408 may have at least one inlet for coolant inlet line 410 and at least one outlet for coolant outlet line 412. The at least one inlet line 410 may receive a flow of liquid coolant from a source external to the server. The at least one outlet line 412 may provide the flow of coolant to one or more components of the server. The cold plate 408 may also include at least one additional outlet line to provide the flow of coolant to external source and may include at least one additional inlet line to receive the flow of coolant from the one or more components of the server.

FIG. 5A illustrates an example cold plate 500 to distribute liquid coolant in computer hardware such as for a computer system, according to at least one embodiment. In at least one embodiment, the cold plate 500 may have, different from the embodiment in FIG. 5B, source fluid adapters 502, 504 and distribution fluid adapters 506, 508 as inlets and outlets of the cold plate 500. The source fluid adapters 502, 504 may enable receipt and egress of the liquid coolant between the cold plate 500 and at least an external liquid coolant source or interface, such as the cooling tower or primary cooling loop illustrated in FIG. 1A, or the rack cooling manifold or the CDU illustrated in FIG. 3. The distribution fluid adapters 506, 508 may enable receipt and egress of the liquid coolant between the cold plate 500 and one or more other components, such as a server the cold plate 500 is located in. The server may also include circuit boards, such as printed circuit boards (PCB) or a collection of PCBs, which are provided cooling from the cold plate 500 or include components which are provided cooling from the cold plate 500. In at least one embodiment, coolant or other fluid flows, as indicated by the arrows, into source inlet fluid adapter 502, through the cold plate 500, and out of the source outlet fluid adapter 504, transferring fluid with the fluid source. The coolant or other fluid may also flow out of the distribution outlet fluid adapter 506 and into the distribution source inlet fluid adapter 508, transferring fluid with the other components. The cold plate 500 may use distribution fluid adapters 506, 508 to also serve as a manifold and distribute the flow of cooling fluid to other hardware components associated with the cold plate 500 of a system associated with the cold plate 500, such as a server tray or box which may be removable from a server rack. In an embodiment, the server tray or box may include more than one cold plate 500 to serve as manifolds. The cold plate 500 may include any number of fluid adapters in various combinations to transfer cooling fluid. The cold plate 500 may also include one or more channels connected to the fluid adapters. In at least one embodiment, the flow of the coolant refers to flow rate or flow volume of the coolant in cold plate 500 or into or out of the cold plate 500. In at least one embodiment, the coolant is in a dynamic state and is continuously moving through the cold plate 500.

The source fluid adapters 502, 504 and distribution fluid adapters 506, 508 may use any suitable connection, such as fixed flow controllers. In at least one embodiment, server trays may have fixed flow controllers (such as blind mate quick disconnects) at determined positions to couple to the cold plate 500, or fluid adapters of the cold plate 500, for coolant flow to the cold plate 500. Such determined positions may not align to provided flow controllers of the cold plate 500. In at least one embodiment, additional flexible tubing may be required. In at least one embodiment, server fluid connection to the cold plate 500 may be made through flexible fixtures (such as a tube) provided within the server trays and that have a fixed blind-mate connection to the cold plate 500 on one side and that has movable blind-mate connection on another side. In at least one embodiment, as the cold plate 500 incorporates a movable flow controller, there is no need for additional flexible tubing that may introduce additional points of potential failure. In at least one embodiment, a movable blind-mate connection (referred to generally as a flow controller) can be moved horizontally and/or vertically for precise mating with flow controllers on a server's side (such as a server face or a coolant source input and output). In at least one embodiment, movement of a movable flow controller enables support to fit various styles of servers in a rack. In at least one embodiment, sensors and intelligent control may be associated with a flow controller or other part, such as within or on the cold plate 500, to enable monitoring.

The cold plate 500 may also have one or more exterior thermal transfer surfaces 510 or cooling surfaces that can be used to provide a source of cooling by thermal transfer with coolant or other fluid. The exterior thermal transfer surfaces 510 of the cold plate 500 may provide cooling to a component 512 associated with the cold plate 500, such as positioned on the exterior thermal transfer surface 510. There may be more than one of the components 512 that receive a source of cooling from the cold plate 500, rather than the flow of liquid coolant, and some components may receive both the source of cooling and the flow of liquid coolant. For example, the components 512 may be any hardware which has a heat generating feature, such as a circuit board, networking card, storage drive, compute block, processing unit, or other component. In an example, the components 512 may be one or more compute devices, compute hardware, processing units, or other suitable hardware. In an embodiment, the compute device may be a distinct assembly of hardware components that can be easily added, removed or replaced in a larger system to allow for the performance of various computations.” The cold plate 500 may therefore act as a cooling source for some components as a traditional cold plate and may also act as a manifold to receive the flow of fluid coolant from a source and distribute the flow to components.

While independent manifolds have been used to receive the flow of coolant to a server tray and then connect to other components, including cold plates, to distribute the coolant within the associated system. These connections may include numerous expensive quick disconnects as well as large hoses over long distances. The independent manifolds and the intermediate connections and hoses take up unnecessary space and add unnecessary cost. In some examples, the manifold may provide a flow of cooling fluid for one or more primary thermal loads, such as compute boards blocks served by cooling plates, which require additional large connections and tubing. Using the cold plate 500 as a manifold for computer hardware can remove both the manifold and at least some connections associated with the manifold, freeing up space, reducing complexity, and lowering cost. Other components of the system requiring a flow of cooling fluids can connect directly with the cold plate 500 instead of with an independent manifold receiving the flow from an external source. In an embodiment, the cold plate 500 may first receive the flow from a manifold and then redistribute at least a portion of the flow. In another embodiment, the cold plate 500 may first receive the flow from an external source and then redistribute at least a portion of the flow to a manifold, as the cold plate 500 also provides a source of cooling to one or more other components, such as illustrated in FIG. 5A. The manifold being fed cooling fluid from the cold plate 500 may be sized smaller than a manifold normally used to meet the capacity needs of the system. For example, the cold plate 500 may provide a flow of cooling fluid to smaller manifold located in the front of the tray where the liquid connections of other components, such as a front input/output (IO) with networking cards and storage drives, plug into or blind mate to the manifold. In this example, the components may have cold cooling blocks with blind mate connections to the smaller capacity manifold.

As power levels rise, more space is taken up by components and cooling needs increase for computer hardware, additional distribution and larger hoses are required to maintain efficient performance. Accordingly, more substantial cooling fluid delivery hardware may be required, such thicker hoses and connections for the higher flow rate, where the hoses have larger diameters and bend radiuses, utilizing even more space. The use of the cold plate 500 as a manifold can reduce the space required by eliminating or reducing these features in the server. Using the cold plate 500 to provide the flow of fluid coolant to other components based on their needs allows for the components to be disaggregated from the cold plate 500. The connections, such as the connectors and hoses, used to provide the flow of fluid coolant to other components directly from the cold plate 500 can be smaller, more malleable, and less expensive, and may be easier to route around the system rather than larger connection parts that may be required for systems that do not utilize the cold plate 500 as a manifold. Also, the components may still be modular, allowing for simplified servicing, such as detaching or unplugging the component from the cold plate 500. In an embodiment, a system may have more than one of the cold plates 500. The more than one cold plates 500 may be connected to each other, such as in series, parallel, or other configurations, while also providing a source of cooling to other components. For example, the one or more cold plates may be able to be connected using at least one daisy chain-style connection including a plurality of hoses and connectors. In an embodiment, the more than one cold plates 500 may be connected to each other and also connected to one or more external coolant fluid sources or interfaces.

FIG. 5B illustrates an example cold plate 550 to distribute liquid coolant in computer hardware such as for a computer system, according to at least one embodiment. In at least one embodiment, the cold plate 550 may have, different from the embodiment in FIG. 5A, a limited number of connections, including an inlet 552 to receive cooling fluid from a remote coolant source 580 and an outlet 554 to distribute cooling fluid to components 590 a computer system associated with the cold plate 550. For example, the inlet 552 may receive cooling fluid from a remote coolant source 580, such as through a liquid coolant loop 570. In another example, the components 590 receiving the cooling fluid distributed from the outlet 554 may be cold plates, manifolds, cooling blocks, or other suitable components. However, one or more fluid plates 550 may have other combinations of fluid adapters configured for fluid connections with one or more sources or one or more other components, and may be configurable to change the number of fluid connections. In an example, the cold plate 550 may include one or more fluid connections with external sources, and may include one or more fluid connections with other components. As shown in FIG. 5B, the cold plate 550 may receive a flow of coolant at the inlet 552 and may distribute the flow of coolant from the outlet 554. The flow of coolant from the outlet 554 may be provided to one or more other components, such as a manifold.

The cold plate 550 may also have one or more exterior thermal transfer surfaces 560 or cooling surface that can be used to provide a source of cooling by thermal transfer with coolant or other fluid. The exterior thermal transfer surfaces 560 of the cold plate 550 may provide a source of cooling to a compute device 562 or other device associated with the cold plate 550, such as positioned on the exterior thermal transfer surface 560. There may be more than one of the compute devices 562 that receive a source of cooling from the cold plate 550, rather than the flow of liquid coolant, and some compute devices may receive both the source of cooling and the flow of liquid coolant. For example, the compute devices 562 may be any hardware which has a heat generating feature, such as a circuit board, networking card, storage drive, compute block, processing unit, or other device. In an example, the compute devices 562 may be one or more compute devices, compute hardware, processing units, or other suitable hardware. In an embodiment, the compute device 562 may be a distinct assembly of hardware components that can be easily added, removed or replaced in a larger system to allow for the performance of various computations. The cold plate 550 may therefore act as a cooling source for some compute devices as a traditional cold plate and may also act as a manifold to receive the flow of fluid coolant from a source and distribute the coolant flow to components.

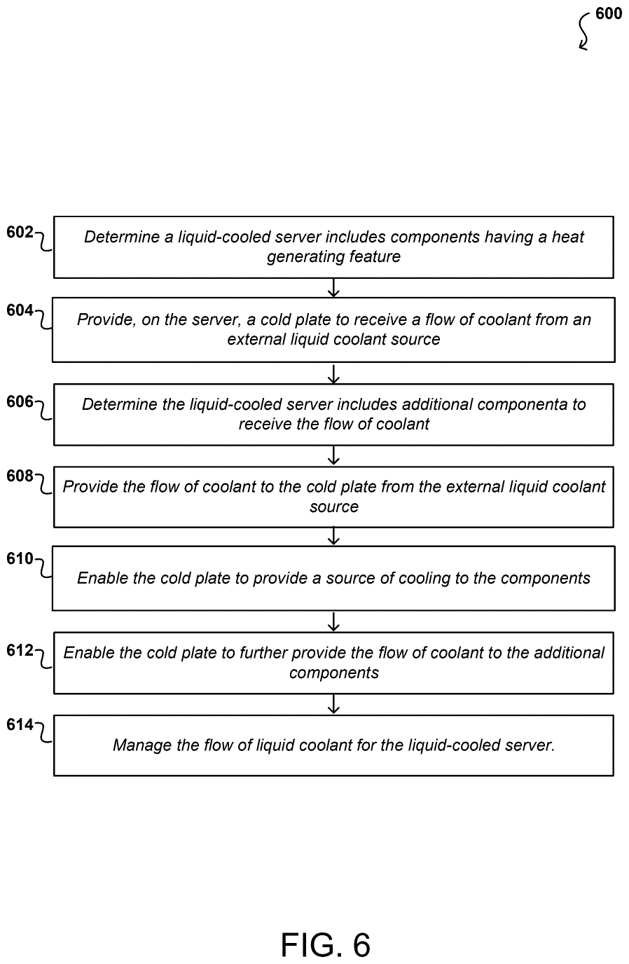

FIG. 6 illustrates an example process 600 that can be performed to use a cold plate as a manifold for a liquid cooled server, according to at least one embodiment. It should be understood that for this and other processes presented herein that there may be additional, fewer, or alternative steps performed or similar or alternative orders, or at least partially in parallel, within the scope of the various embodiments unless otherwise specifically stated. Further, although this and other examples herein will be discussed with respect to coolant flow and thermal properties for servers and related components, there can be other types of parameters and measurements determined for other types of cooling systems or devices as well, within the scope of various embodiments. In this example, a liquid-cooled server is determined 602 to include a component having a heat generating feature. The liquid cooled server may be a server tray or box having one or more circuit boards, and may be located in a rack able to receive a plurality of servers. The liquid cooled server may include a plurality of component having a heat generating feature, such as processing units, storage drives, compute devices, sensors, cards, circuit boards, memory, hubs, controllers, interfaces, networking devices, circuits, or other components. One or more cold plates can be provided 604 on the server to receive a flow of coolant from an external liquid coolant source. The cold plates may be able to fluidly connect with the external liquid coolant source, such as using any of at least an interface, a coolant loop, inlets and outlets, and a plurality of connectors and hoses. The cold plates may have one or more surfaces that the components having a heat generating feature can be positioned on. The cold plates may be fluidly connected together, such as in a daisy-chain configuration. The liquid-cooled server is determined 606 to include at least one additional component to receive the flow of coolant. The liquid cooled server may include a plurality of component to receive the flow of coolant, such as manifold, other cold plates, pumps, blocks, or other components. The components may include a plurality of connectors and hoses for fluid connections, such as with the cold plates.

The flow of coolant is provided 608 to the cold plates from the external liquid coolant source. An interface may be used between the cold plates and the external liquid coolant source. The interface may be part of the liquid cooled server. The flow of coolant may be received to a first cold plate without an intervening manifold in the server housing. More than one external liquid coolant source may provide flows of coolant to the cold plates. The cold plates may be able to connect to the flow of liquid coolant using a manual connection or a blind mate connection. The one or more cold plates are enabled 610 to provide a source of cooling to the at least one component having a heat generating feature. The components may be positioned on one or more surfaces of the cold plates to receive the source of cooling, where the surfaces are cooled by the flow of coolant in contact with the surfaces. The one or more cold plates are enabled 612 to further provide the flow of coolant to the at least one additional component. The components may be in fluid communication with the cold plates. The flow of coolant may be transferred using a plurality of hoses and connections. Hoses transferring the fluid to the components may be routed through the liquid-cooled server. The flow of coolant may be provided from the cold plates to manifolds before being provided to at least some of the components. The components may provide the flow of coolant back to the cold plates. The cold plates may provide the flow of coolant back to the external liquid coolant source. The flow of coolant is managed 614 for the liquid-cooled server. One or more flow rate sensors or leakage sensors may be used to monitor the flow of coolant, such as for per-route flow telemetry. The sensor data may be passed to a data aggregator, such as at a system level or a data center level, including any one or more of a board management controller (BMC), a field programmable gate arrays (FPGA), an external wired server, or other components. Flow rate balancing of the flow of coolant may be manually or programmatically performed through flow dampers or flow controllers, such as integral with the cold plate. The flow dampers may be operated using external manual or automated end effectors. The cold plate may limit backflow and/or crossflow between the flow of coolant to the components to receive the flow of coolant distributed from the cold plate.

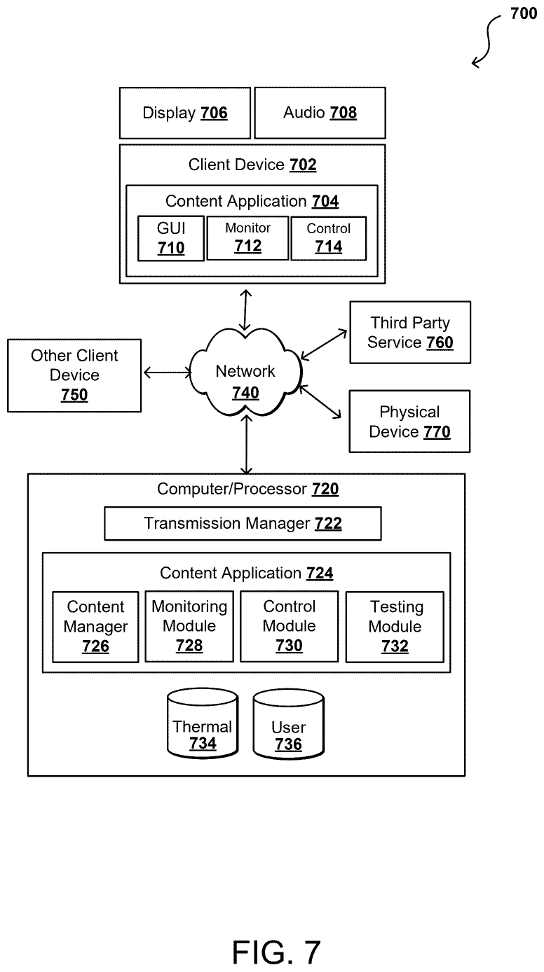

FIG. 7 illustrates an example network configuration 700 of components that can be used to implement aspects of various embodiments, such as to provide, generate, modify, encode, process, fuse, and/or transmit liquid coolant data or server thermal data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant data or server thermal data to be selected and/or retrieved from a repository 734 to be used by a testing module 732 to calculate one or more performance metrics for a monitoring module 728, which can provide flow data or thermal data to a control module 730 to control a flow or temperature, in an environment where the data is to be used to determine appropriate operation. A content manager 726 may work with at these various modules to perform testing and analysis, and potentially instruct any actions to be taken in response to a performance metric failing to satisfy an operational requirements. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface 710, a flow monitor module 712, and a control module 714 for use in providing, synthesizing, rendering, compositing, modifying, or using content for presentation, navigation, control, (or other purposes) on or by the client device 702, such as may be transmitted to the physical device 770. In some embodiments, the computer/processor 720 and client device 702 may be able to communicate directly without needing to transmit data over a network 740, in order to avoid issues with latency and availability, etc. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

### Data Center

Data centers may use air cooling to cool servers to prevent malfunction due to high heat. Air cooling of high density servers has become inefficient and ineffective in view of high heat requirements caused by present day computing devices. Often, air cooling is insufficient to properly cool computing devices in present day data centers. In at least one embodiment, to remedy this some servers use liquid cooling to cool high-power components such as CPUs, GPUs, other processing units, or the like. In at least one embodiment, cold plates that receive a liquid coolant are coupled to high-power components. In at least one embodiment, cold plates can transfer heat energy from a component to a flowing liquid coolant. In at least one embodiment, liquid coolant is flowed from a cold plate to a distribution unit (e.g., a coolant distribution unit (CDU), etc.) where heat is rejected from coolant. In at least one embodiment, cooled liquid coolant is then flowed back to cold plates to remove more heat from server components. Although high-power components can be cooled with liquid coolant via cold plates, low-power components are still cooled via air cooling. Cooling low-power components with air requires energy to run fans to move air through servers. Air has a relatively low heat capacity, so a large amount of air is moved over server components to provide proper cooling. Although cooling efficiency may be increased by cooling high-power server components via liquid cooling in data centers, cooling low-power server components via air cooling hampers cooling efficiency in data centers.

Some data centers cool servers (e.g., server components) via liquid immersion cooling. In some data centers, entire server units are submerged in a vat (e.g., a tank, a tub, a pool, etc.) of dielectric liquid coolant. Heat from server components (e.g., both high-power server components and low-power server components) is transferred to dielectric liquid coolant. Often, dielectric liquid coolant has a greater heat capacity than air, meaning that server components are more effectively cooled than by air cooling. However, dielectric liquid coolant may have a lower heat capacity than other liquid coolants, such as water, that may be used for cold plate cooling as described above. Thus, high-power server components may not be efficiently and/or effectively cooled by immersion cooling.

In at least one embodiment, a cooling system for a data center has dual-cooling modes. In at least one embodiment, a data center cooling system includes one or more first cooling loops that flow a first coolant to cool high-power server components via cold plates and one or more second cooling loops that flow a second coolant to cool low-power server components via immersion cooling. In at least one embodiment, a data center server receives a first coolant from a first CDU. First coolant may be routed through piping, tubing, and/or one or more manifolds along one or more first flow paths between a first CDU and one or more servers. In at least one embodiment, one or more servers are disposed in a data center rack (e.g., supported in a rack of a data center). First coolant may flow into a server chassis through a first inlet. In at least one embodiment, first coolant is flowed through one or more cold plates coupled to one or more high-power components such as a CPU, GPU, etc. within a server chassis. First coolant may receive heat from one or more high-power components and flow out of a server chassis through a first outlet. Once out of a server chassis, first coolant may flow through piping, tubing, and/or one or more manifolds along one or more first flow paths to a first CDU where first coolant is cooled then returned back to one or more servers along one or more first flow paths. In at least one embodiment, a first CDU may cause heat to be exchanged between first coolant and another coolant such as water. Another coolant may be flowed from a first CDU to a cooling tower, chiller, dry cooler, etc. where heat from first coolant is rejected to an ambient environment. In at least one embodiment, a first flow path is a loop along which first coolant flows.

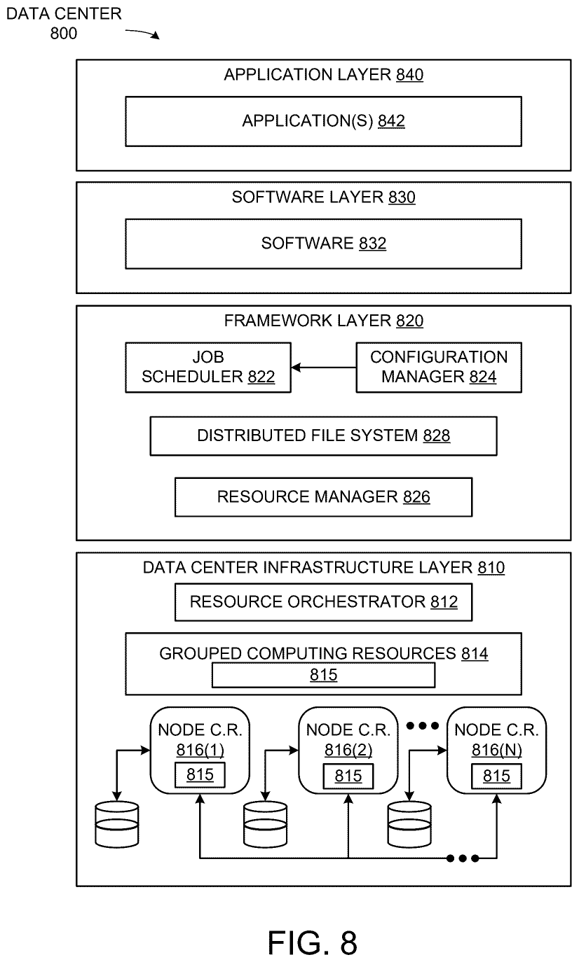

FIG. 8 illustrates an example data center 800, in which at least one embodiment may be used. In at least one embodiment, data center 800 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents a positive integer (which may be a different integer “N” than used in other figures). In at least one embodiment, node C.R.s 816(1)-816(N) may include, but are not limited to, any number of central processing units (“CPUs”) or other processors (including accelerators, field programmable gate arrays (FPGAs), graphics processors, etc.), memory storage devices 818(1)-818(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). In at least one embodiment, separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 800. In at least one embodiment, resource orchestrator 812 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may use distributed file system 828 for large-scale data processing (e.g., “big data”). In at least one embodiment, job scheduler 822 may include a Spark driver to facilitate scheduling of workloads supported by various layers of data center 800. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of distributed file system 828 and job scheduler 822. In at least one embodiment, clustered or grouped computing resources may include grouped computing resources 814 at data center infrastructure layer 810. In at least one embodiment, resource manager 826 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. In at least one embodiment, one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 824, resource manager 826, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underused and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 815 are used to perform inferencing and/or training operations associated with one or more embodiments. In at least one embodiment, inference and/or training logic 815 may be used in system FIG. 8 for inferencing or predicting operations based, at least in part, on weight parameters calculated using neural network training operations, neural network functions and/or architectures, or neural network use cases described herein.

Embodiments presented herein include cold plates in computer hardware.

### Servers and Data Centers

The following figures set forth, without limitation, exemplary network server and data center based systems that can be used to implement at least one embodiment.

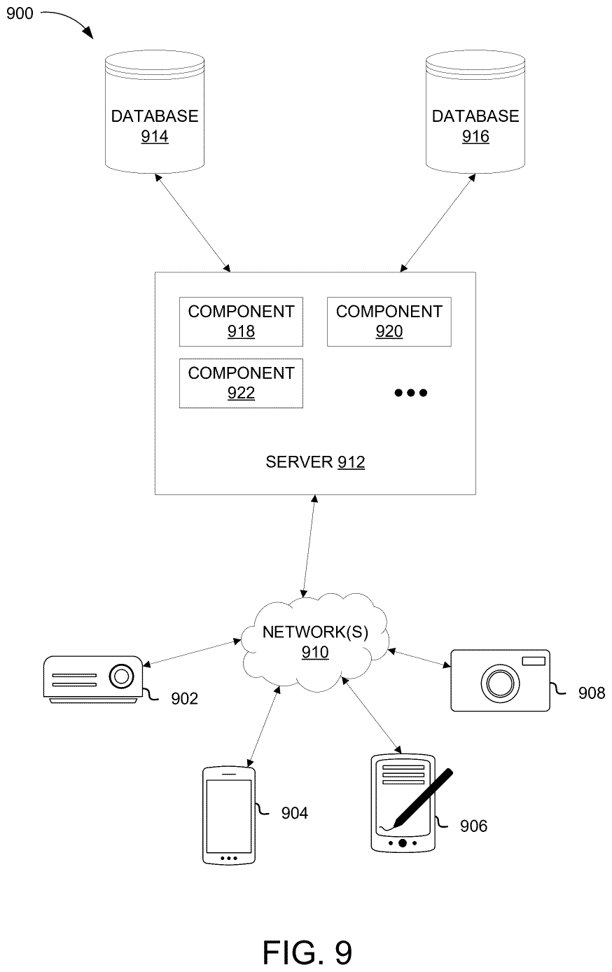

FIG. 9 illustrates a distributed system 900, in accordance with at least one embodiment. In at least one embodiment, distributed system 900 includes one or more client computing devices 902, 904, 906, and 908, which are configured to execute and operate a client application such as a web browser, proprietary client, and/or variations thereof over one or more network(s) 910. In at least one embodiment, server 912 may be communicatively coupled with remote client computing devices 902, 904, 906, and 908 via network 910.

In at least one embodiment, server 912 may be adapted to run one or more services or software applications such as services and applications that may manage session activity of single sign-on (SSO) access across multiple data centers. In at least one embodiment, server 912 may also provide other services or software applications can include non-virtual and virtual environments. In at least one embodiment, these services may be offered as web-based or cloud services or under a Software as a Service (SaaS) model to users of client computing devices 902, 904, 906, and/or 908. In at least one embodiment, users operating client computing devices 902, 904, 906, and/or 908 may in turn utilize one or more client applications to interact with server 912 to utilize services provided by these components.

In at least one embodiment, software components 918, 920, and 922 of distributed system 900 are implemented on server 912. In at least one embodiment, one or more components of distributed system 900 and/or services provided by these components may also be implemented by one or more of client computing devices 902, 904, 906, and/or 908. In at least one embodiment, users operating client computing devices may then utilize one or more client applications to use services provided by these components. In at least one embodiment, these components may be implemented in hardware, firmware, software, or combinations thereof. It should be appreciated that various different system configurations are possible, which may be different from distributed system 900. The embodiment shown in FIG. 9 is thus one example of a distributed system for implementing an embodiment system and is not intended to be limiting.

In at least one embodiment, client computing devices 902, 904, 906, and/or 908 may include various types of computing systems. In at least one embodiment, a client computing device may include portable handheld devices (e.g., an iPhone®, cellular telephone, an iPad®, computing tablet, a personal digital assistant (PDA)) or wearable devices (e.g., a Google Glass® head mounted display), running software such as Microsoft Windows Mobile®, and/or a variety of mobile operating systems such as iOS, Windows Phone, Android, BlackBerry 10, Palm OS, and/or variations thereof. In at least one embodiment, devices may support various applications such as various Internet-related apps, e-mail, short message service (SMS) applications, and may use various other communication protocols. In at least one embodiment, client computing devices may also include general purpose personal computers including, by way of example, personal computers and/or laptop computers running various versions of Microsoft Windows®, Apple Macintosh®, and/or Linux operating systems. In at least one embodiment, client computing devices can be workstation computers running any of a variety of commercially-available UNIX® or UNIX-like operating systems, including without limitation a variety of GNU/Linux operating systems, such as Google Chrome OS. In at least one embodiment, client computing devices may also include electronic devices such as a thin-client computer, an Internet-enabled gaming system (e.g., a Microsoft Xbox gaming console with or without a Kinect® gesture input device), and/or a personal messaging device, capable of communicating over network(s) 910. Although distributed system 900 in FIG. 9 is shown with four client computing devices, any number of client computing devices may be supported. Other devices, such as devices with sensors, etc., may interact with server 912.

In at least one embodiment, network(s) 910 in distributed system 900 may be any type of network that can support data communications using any of a variety of available protocols, including without limitation TCP/IP (transmission control protocol/Internet protocol), SNA (systems network architecture), IPX (Internet packet exchange), AppleTalk, and/or variations thereof. In at least one embodiment, network(s) 910 can be a local area network (LAN), networks based on Ethernet, Token-Ring, a wide-area network, Internet, a virtual network, a virtual private network (VPN), an intranet, an extranet, a public switched telephone network (PSTN), an infra-red network, a wireless network (e.g., a network operating under any of the Institute of Electrical and Electronics (IEEE) 802.11 suite of protocols, Bluetooth®, and/or any other wireless protocol), and/or any combination of these and/or other networks.

In at least one embodiment, server 912 may be composed of one or more general purpose computers, specialized server computers (including, by way of example, PC (personal computer) servers, UNIX® servers, mid-range servers, mainframe computers, rack-mounted servers, etc.), server farms, server clusters, or any other appropriate arrangement and/or combination. In at least one embodiment, server 912 can include one or more virtual machines running virtual operating systems, or other computing architectures involving virtualization. In at least one embodiment, one or more flexible pools of logical storage devices can be virtualized to maintain virtual storage devices for a server. In at least one embodiment, virtual networks can be controlled by server 912 using software defined networking. In at least one embodiment, server 912 may be adapted to run one or more services or software applications.

In at least one embodiment, server 912 may run any operating system, as well as any commercially available server operating system. In at least one embodiment, server 912 may also run any of a variety of additional server applications and/or mid-tier applications, including HTTP (hypertext transport protocol) servers, FTP (file transfer protocol) servers, CGI (common gateway interface) servers, JAVA® servers, database servers, and/or variations thereof. In at least one embodiment, exemplary database servers include without limitation those commercially available from Oracle, Microsoft, Sybase, IBM (International Business Machines), and/or variations thereof.

In at least one embodiment, server 912 may include one or more applications to analyze and consolidate data feeds and/or event updates received from users of client computing devices 902, 904, 906, and 908. In at least one embodiment, data feeds and/or event updates may include, but are not limited to, Twitter® feeds, Facebook® updates or real-time updates received from one or more third party information sources and continuous data streams, which may include real-time events related to sensor data applications, financial tickers, network performance measuring tools (e.g., network monitoring and traffic management applications), clickstream analysis tools, automobile traffic monitoring, and/or variations thereof. In at least one embodiment, server 912 may also include one or more applications to display data feeds and/or real-time events via one or more display devices of client computing devices 902, 904, 906, and 908.

In at least one embodiment, distributed system 900 may also include one or more databases 914 and 916. In at least one embodiment, databases may provide a mechanism for storing information such as user interactions information, usage patterns information, adaptation rules information, and other information. In at least one embodiment, databases 914 and 916 may reside in a variety of locations. In at least one embodiment, one or more of databases 914 and 916 may reside on a non-transitory storage medium local to (and/or resident in) server 912. In at least one embodiment, databases 914 and 916 may be remote from server 912 and in communication with server 912 via a network-based or dedicated connection. In at least one embodiment, databases 914 and 916 may reside in a storage-area network (SAN). In at least one embodiment, any necessary files for performing functions attributed to server 912 may be stored locally on server 912 and/or remotely, as appropriate. In at least one embodiment, databases 914 and 916 may include relational databases, such as databases that are adapted to store, update, and retrieve data in response to SQL-formatted commands.

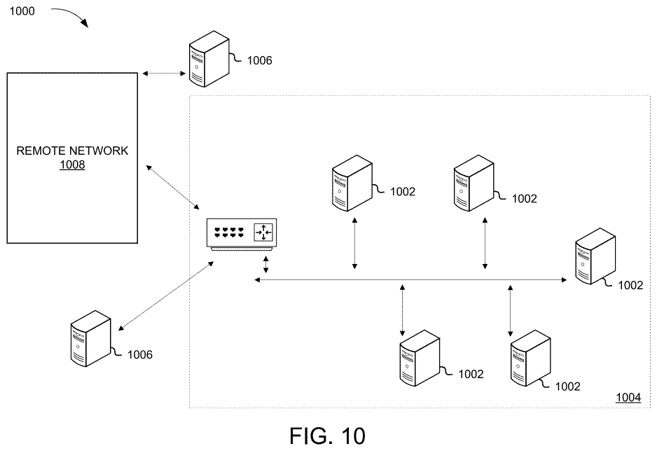

FIG. 10 illustrates a system 1000 that includes a client-server network 1004 formed by a plurality of network server computers 1002 which are interlinked, in accordance with at least one embodiment. In at least one embodiment, each network server computer 1002 stores data accessible to other network server computers 1002 and to client computers 1006 and networks 1008 which link into a wide area network 1004. In at least one embodiment, configuration of a client-server network 1004 may change over time as client computers 1006 and one or more networks 1008 connect and disconnect from a network 1004, and as one or more trunk line server computers 1002 are added or removed from a network 1004. In at least one embodiment, when a client computer 1006 and a network 1008 are connected with network server computers 1002, client-server network includes such client computer 1006 and network 1008. In at least one embodiment, the term computer includes any device or machine capable of accepting data, applying prescribed processes to data, and supplying results of processes.

In at least one embodiment, client-server network 1004 stores information which is accessible to network server computers 1002, remote networks 1008 and client computers 1006. In at least one embodiment, network server computers 1002 are formed by main frame computers minicomputers, and/or microcomputers having one or more processors each. In at least one embodiment, server computers 1002 are linked together by wired and/or wireless transfer media, such as conductive wire, fiber optic cable, and/or microwave transmission media, satellite transmission media or other conductive, optic or electromagnetic wave transmission media. In at least one embodiment, client computers 1006 access a network server computer 1002 by a similar wired or a wireless transfer medium. In at least one embodiment, a client computer 1006 may link into a client-server network 1004 using a modem and a standard telephone communication network. In at least one embodiment, alternative carrier systems such as cable and satellite communication systems also may be used to link into client-server network 1004. In at least one embodiment, other private or time-shared carrier systems may be used. In at least one embodiment, network 1004 is a global information network, such as the Internet. In at least one embodiment, network is a private intranet using similar protocols as the Internet, but with added security measures and restricted access controls. In at least one embodiment, network 1004 is a private, or semi-private network using proprietary communication protocols.

In at least one embodiment, client computer 1006 is any end user computer, and may also be a mainframe computer, mini-computer or microcomputer having one or more microprocessors. In at least one embodiment, server computer 1002 may at times function as a client computer accessing another server computer 1002. In at least one embodiment, remote network 1008 may be a local area network, a network added into a wide area network through an independent service provider (ISP) for the Internet, or another group of computers interconnected by wired or wireless transfer media having a configuration which is either fixed or changing over time. In at least one embodiment, client computers 1006 may link into and access a network 1004 independently or through a remote network 1008.

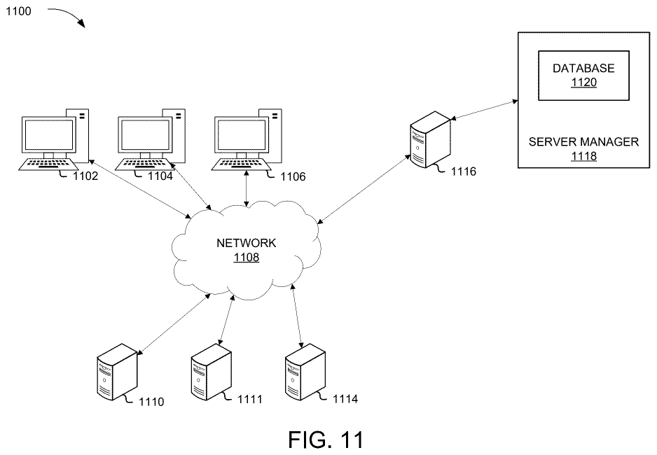

FIG. 11 illustrates a computer network 1108 connecting one or more computing machines, in accordance with at least one embodiment. In at least one embodiment, network 1108 may be any type of electronically connected group of computers including, for instance, the following networks: Internet, Intranet, Local Area Networks (LAN), Wide Area Networks (WAN) or an interconnected combination of these network types. In at least one embodiment, connectivity within a network 1108 may be a remote modem, Ethernet (IEEE 802.3), Token Ring (IEEE 802.5), Fiber Distributed Datalink Interface (FDDI), Asynchronous Transfer Mode (ATM), or any other communication protocol. In at least one embodiment, computing devices linked to a network may be desktop, server, portable, handheld, set-top box, personal digital assistant (PDA), a terminal, or any other desired type or configuration. In at least one embodiment, depending on their functionality, network connected devices may vary widely in processing power, internal memory, and other performance aspects. In at least one embodiment, communications within a network and to or from computing devices connected to a network may be either wired or wireless. In at least one embodiment, network 1108 may include, at least in part, the world-wide public Internet which generally connects a plurality of users in accordance with a client-server model in accordance with a transmission control protocol/internet protocol (TCP/IP) specification. In at least one embodiment, client-server network is a dominant model for communicating between two computers. In at least one embodiment, a client computer (“client”) issues one or more commands to a server computer (“server”). In at least one embodiment, server fulfills client commands by accessing available network resources and returning information to a client pursuant to client commands. In at least one embodiment, client computer systems and network resources resident on network servers are assigned a network address for identification during communications between elements of a network. In at least one embodiment, communications from other network connected systems to servers will include a network address of a relevant server/network resource as part of communication so that an appropriate destination of a data/request is identified as a recipient. In at least one embodiment, when a network 1108 comprises the global Internet, a network address is an IP address in a TCP/IP format which may, at least in part, route data to an e-mail account, a website, or other Internet tool resident on a server. In at least one embodiment, information and services which are resident on network servers may be available to a web browser of a client computer through a domain name (e.g., www.site.com) which maps to an IP address of a network server.

In at least one embodiment, a plurality of clients 1102, 1104, and 1106 are connected to a network 1108 via respective communication links. In at least one embodiment, each of these clients may access a network 1108 via any desired form of communication, such as via a dial-up modem connection, cable link, a digital subscriber line (DSL), wireless or satellite link, or any other form of communication. In at least one embodiment, each client may communicate using any machine that is compatible with a network 1108, such as a personal computer (PC), work station, dedicated terminal, personal data assistant (PDA), or other similar equipment. In at least one embodiment, clients 1102, 1104, and 1106 may or may not be located in a same geographical area.

In at least one embodiment, a plurality of servers 1110, 1112, and 1114 are connected to a network 1108 to serve clients that are in communication with a network 1108. In at least one embodiment, each server is typically a powerful computer or device that manages network resources and responds to client commands. In at least one embodiment, servers include computer readable data storage media such as hard disk drives and RAM memory that store program instructions and data. In at least one embodiment, servers 1110, 1112, 1114 run application programs that respond to client commands. In at least one embodiment, server 1110 may run a web server application for responding to client requests for HTML pages and may also run a mail server application for receiving and routing electronic mail. In at least one embodiment, other application programs, such as an FTP server or a media server for streaming audio/video data to clients may also be running on a server 1110. In at least one embodiment, different servers may be dedicated to performing different tasks. In at least one embodiment, server 1110 may be a dedicated web server that manages resources relating to web sites for various users, whereas a server 1112 may be dedicated to provide electronic mail (email) management. In at least one embodiment, other servers may be dedicated for media (audio, video, etc.), file transfer protocol (FTP), or a combination of any two or more services that are typically available or provided over a network. In at least one embodiment, each server may be in a location that is the same as or different from that of other servers. In at least one embodiment, there may be multiple servers that perform mirrored tasks for users, thereby relieving congestion or minimizing traffic directed to and from a single server. In at least one embodiment, servers 1110, 1112, 1114 are under control of a web hosting provider in a business of maintaining and delivering third party content over a network 1108.

In at least one embodiment, web hosting providers deliver services to two different types of clients. In at least one embodiment, one type, which may be referred to as a browser, requests content from servers 1110, 1112, 1114 such as web pages, email messages, video clips, etc. In at least one embodiment, a second type, which may be referred to as a user, hires a web hosting provider to maintain a network resource such as a web site, and to make it available to browsers. In at least one embodiment, users contract with a web hosting provider to make memory space, processor capacity, and communication bandwidth available for their desired network resource in accordance with an amount of server resources a user desires to utilize.

In at least one embodiment, in order for a web hosting provider to provide services for both of these clients, application programs which manage a network resources hosted by servers must be properly configured. In at least one embodiment, program configuration process involves defining a set of parameters which control, at least in part, an application program's response to browser requests and which also define, at least in part, a server resources available to a particular user.

In one embodiment, an intranet server 1116 is in communication with a network 1108 via a communication link. In at least one embodiment, intranet server 1116 is in communication with a server manager 1118. In at least one embodiment, server manager 1118 comprises a database of an application program configuration parameters which are being utilized in servers 1110, 1112, 1114. In at least one embodiment, users modify a database 1120 via an intranet 1116, and a server manager 1118 interacts with servers 1110, 1112, 1114 to modify application program parameters so that they match a content of a database. In at least one embodiment, a user logs onto an intranet server 1116 by connecting to an intranet 1116 via computer 1102 and entering authentication information, such as a username and password.

In at least one embodiment, when a user wishes to sign up for new service or modify an existing service, an intranet server 1116 authenticates a user and provides a user with an interactive screen display/control panel that allows a user to access configuration parameters for a particular application program. In at least one embodiment, a user is presented with a number of modifiable text boxes that describe aspects of a configuration of a user's web site or other network resource. In at least one embodiment, if a user desires to increase memory space reserved on a server for its web site, a user is provided with a field in which a user specifies a desired memory space. In at least one embodiment, in response to receiving this information, an intranet server 1116 updates a database 1120. In at least one embodiment, server manager 1118 forwards this information to an appropriate server, and a new parameter is used during application program operation. In at least one embodiment, an intranet server 1116 is configured to provide users with access to configuration parameters of hosted network resources (e.g., web pages, email, FTP sites, media sites, etc.), for which a user has contracted with a web hosting service provider.

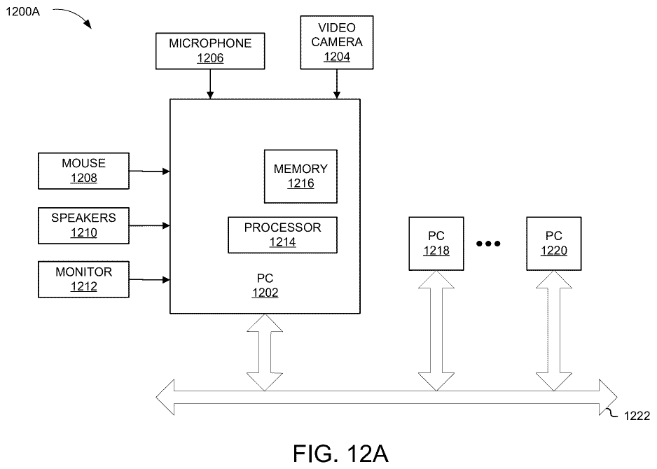

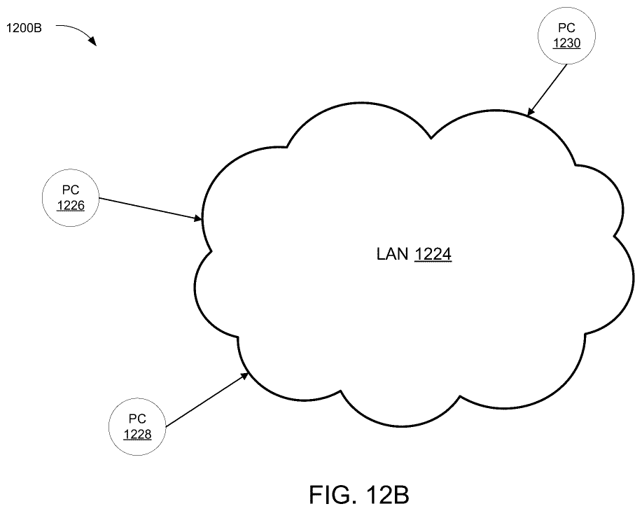

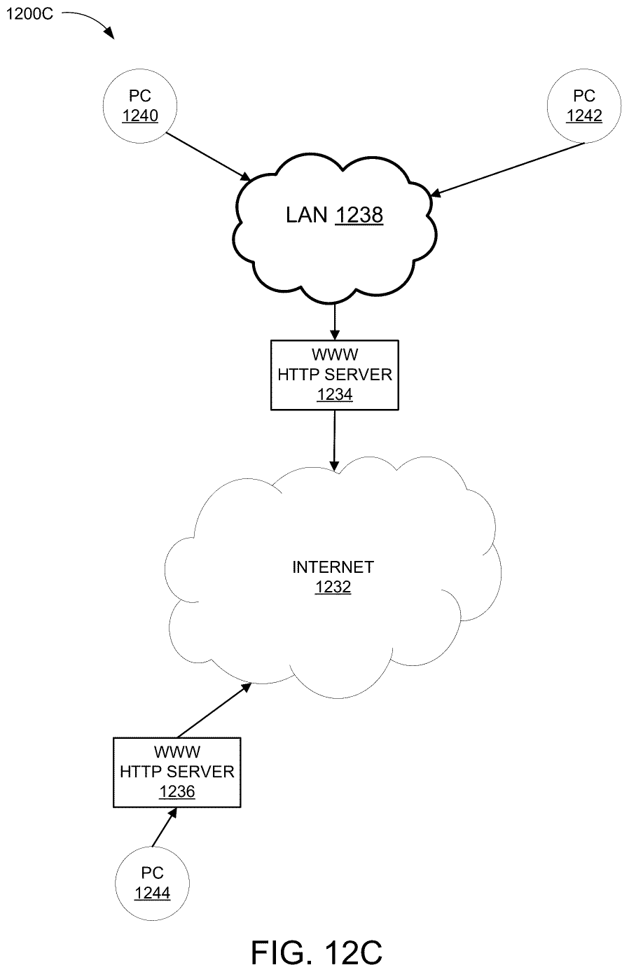

FIG. 12A illustrates a networked computer system 1200A, in accordance with at least one embodiment. In at least one embodiment, networked computer system 1200A comprises a plurality of nodes or personal computers (“PCs”) 1202, 1218, 1220. In at least one embodiment, personal computer or node 1202 comprises a processor 1214, memory 1216, video camera 1204, microphone 1206, mouse 1208, speakers 1210, and monitor 1212. In at least one embodiment, PCs 1202, 1218, 1220 may each run one or more desktop servers of an internal network within a given company, for instance, or may be servers of a general network not limited to a specific environment. In at least one embodiment, there is one server per PC node of a network, so that each PC node of a network represents a particular network server, having a particular network URL address. In at least one embodiment, each server defaults to a default web page for that server's user, which may itself contain embedded URLs pointing to further subpages of that user on that server, or to other servers or pages on other servers on a network.

In at least one embodiment, nodes 1202, 1218, 1220 and other nodes of a network are interconnected via medium 1222. In at least one embodiment, medium 1222 may be, a communication channel such as an Integrated Services Digital Network (“ISDN”). In at least one embodiment, various nodes of a networked computer system may be connected through a variety of communication media, including local area networks (“LANs”), plain-old telephone lines (“POTS”), sometimes referred to as public switched telephone networks (“PSTN”), and/or variations thereof. In at least one embodiment, various nodes of a network may also constitute computer system users inter-connected via a network such as the Internet. In at least one embodiment, each server on a network (running from a particular node of a network at a given instance) has a unique address or identification within a network, which may be specifiable in terms of an URL.

In at least one embodiment, a plurality of multi-point conferencing units (“MCUs”) may thus be utilized to transmit data to and from various nodes or “endpoints” of a conferencing system. In at least one embodiment, nodes and/or MCUs may be interconnected via an ISDN link or through a local area network (“LAN”), in addition to various other communications media such as nodes connected through the Internet. In at least one embodiment, nodes of a conferencing system may, in general, be connected directly to a communications medium such as a LAN or through an MCU, and that a conferencing system may comprise other nodes or elements such as routers, servers, and/or variations thereof.

In at least one embodiment, processor 1214 is a general-purpose programmable processor. In at least one embodiment, processors of nodes of networked computer system 1200A may also be special-purpose video processors. In at least one embodiment, various peripherals and components of a node such as those of node 1202 may vary from those of other nodes. In at least one embodiment, node 1218 and node 1220 may be configured identically to or differently than node 1202. In at least one embodiment, a node may be implemented on any suitable computer system in addition to PC systems.

FIG. 12B illustrates a networked computer system 1200B, in accordance with at least one embodiment. In at least one embodiment, system 1200B illustrates a network such as LAN 1224, which may be used to interconnect a variety of nodes that may communicate with each other. In at least one embodiment, attached to LAN 1224 are a plurality of nodes such as PC nodes 1226, 1228, 1230. In at least one embodiment, a node may also be connected to the LAN via a network server or other means. In at least one embodiment, system 1200B comprises other types of nodes or elements, for example including routers, servers, and nodes.

FIG. 12C illustrates a networked computer system 1200C, in accordance with at least one embodiment. In at least one embodiment, system 1200C illustrates a WWW system having communications across a backbone communications network such as Internet 1232, which may be used to interconnect a variety of nodes of a network. In at least one embodiment, WWW is a set of protocols operating on top of the Internet, and allows a graphical interface system to operate thereon for accessing information through the Internet. In at least one embodiment, attached to Internet 1232 in WWW are a plurality of nodes such as PCs 1240, 1242, 1244. In at least one embodiment, a node is interfaced to other nodes of WWW through a WWW HTTP server such as servers 1234, 1236. In at least one embodiment, PC 1244 may be a PC forming a node of Internet 1232 and itself running its server 1236, although PC 1244 and server 1236 are illustrated separately in FIG. 12C for illustrative purposes.

In at least one embodiment, WWW is a distributed type of application, characterized by WWW HTTP, WWW's protocol, which runs on top of the Internet's transmission control protocol/Internet protocol (“TCP/IP”). In at least one embodiment, WWW may thus be characterized by a set of protocols (i.e., HTTP) running on the Internet as its “backbone.”

In at least one embodiment, a web browser is an application running on a node of a network that, in WWW-compatible type network systems, allows users of a particular server or node to view such information and thus allows a user to search graphical and text-based files that are linked together using hypertext links that are embedded in documents or files available from servers on a network that understand HTTP. In at least one embodiment, when a given web page of a first server associated with a first node is retrieved by a user using another server on a network such as the Internet, a document retrieved may have various hypertext links embedded therein and a local copy of a page is created local to a retrieving user. In at least one embodiment, when a user clicks on a hypertext link, locally-stored information related to a selected hypertext link is typically sufficient to allow a user's machine to open a connection across the Internet to a server indicated by a hypertext link.

In at least one embodiment, more than one user may be coupled to each HTTP server, for example through a LAN such as LAN 1238 as illustrated with respect to WWW HTTP server 1234. In at least one embodiment, system 1200C may also comprise other types of nodes or elements. In at least one embodiment, a WWW HTTP server is an application running on a machine, such as a PC. In at least one embodiment, each user may be considered to have a unique “server,” as illustrated with respect to PC 1244. In at least one embodiment, a server may be considered to be a server such as WWW HTTP server 1234, which provides access to a network for a LAN or plurality of nodes or plurality of LANs. In at least one embodiment, there are a plurality of users, each having a desktop PC or node of a network, each desktop PC potentially establishing a server for a user thereof. In at least one embodiment, each server is associated with a particular network address or URL, which, when accessed, provides a default web page for that user. In at least one embodiment, a web page may contain further links (embedded URLs) pointing to further subpages of that user on that server, or to other servers on a network or to pages on other servers on a network.

### Cloud Computing and Services

The following figures set forth, without limitation, exemplary cloud-based systems that can be used to implement at least one embodiment.

In at least one embodiment, cloud computing is a style of computing in which dynamically scalable and often virtualized resources are provided as a service over the Internet. In at least one embodiment, users need not have knowledge of, expertise in, or control over technology infrastructure, which can be referred to as “in the cloud,” that supports them. In at least one embodiment, cloud computing incorporates infrastructure as a service, platform as a service, software as a service, and other variations that have a common theme of reliance on the Internet for satisfying computing needs of users. In at least one embodiment, a typical cloud deployment, such as in a private cloud (e.g., enterprise network), or a data center (DC) in a public cloud (e.g., Internet) can consist of thousands of servers (or alternatively, VMs), hundreds of Ethernet, Fiber Channel or Fiber Channel over Ethernet (FCOE) ports, switching and storage infrastructure, etc. In at least one embodiment, cloud can also consist of network services infrastructure like IPsec VPN hubs, firewalls, load balancers, wide area network (WAN) optimizers etc. In at least one embodiment, remote subscribers can access cloud applications and services securely by connecting via a VPN tunnel, such as an IPsec VPN tunnel.

In at least one embodiment, cloud computing is a model for enabling convenient, on-demand network access to a shared pool of configurable computing resources (e.g., networks, servers, storage, applications, and services) that can be rapidly provisioned and released with minimal management effort or service provider interaction.

In at least one embodiment, cloud computing is characterized by on-demand self-service, in which a consumer can unilaterally provision computing capabilities, such as server time and network storage, as needed automatically without requiring human inter-action with each service's provider. In at least one embodiment, cloud computing is characterized by broad network access, in which capabilities are available over a network and accessed through standard mechanisms that promote use by heterogeneous thin or thick client platforms (e.g., mobile phones, laptops, and PDAs). In at least one embodiment, cloud computing is characterized by resource pooling, in which a provider's computing resources are pooled to serve multiple consumers using a multi-tenant model, with different physical and virtual resources dynamically as-signed and reassigned according to consumer demand. In at least one embodiment, there is a sense of location independence in that a customer generally has no control or knowledge over an exact location of provided resources, but may be able to specify location at a higher level of abstraction (e.g., country, state, or data center). In at least one embodiment, examples of resources include storage, processing, memory, network bandwidth, and virtual machines. In at least one embodiment, cloud computing is characterized by rapid elasticity, in which capabilities can be rapidly and elastically provisioned, in some cases automatically, to quickly scale out and rapidly released to quickly scale in. In at least one embodiment, to a consumer, capabilities available for provisioning often appear to be unlimited and can be purchased in any quantity at any time. In at least one embodiment, cloud computing is characterized by measured service, in which cloud systems automatically control and optimize resource use by leveraging a metering capability at some level of abstraction appropriate to a type of service (e.g., storage, processing, bandwidth, and active user accounts). In at least one embodiment, resource usage can be monitored, controlled, and reported providing transparency for both a provider and consumer of a utilized service.

In at least one embodiment, cloud computing may be associated with various services. In at least one embodiment, cloud Software as a Service (SaaS) may refer to as service in which a capability provided to a consumer is to use a provider's applications running on a cloud infrastructure. In at least one embodiment, applications are accessible from various client devices through a thin client interface such as a web browser (e.g., web-based email). In at least one embodiment, consumer does not manage or control underlying cloud infrastructure including network, servers, operating systems, storage, or even individual application capabilities, with a possible exception of limited user-specific application configuration settings.

### Computer Systems

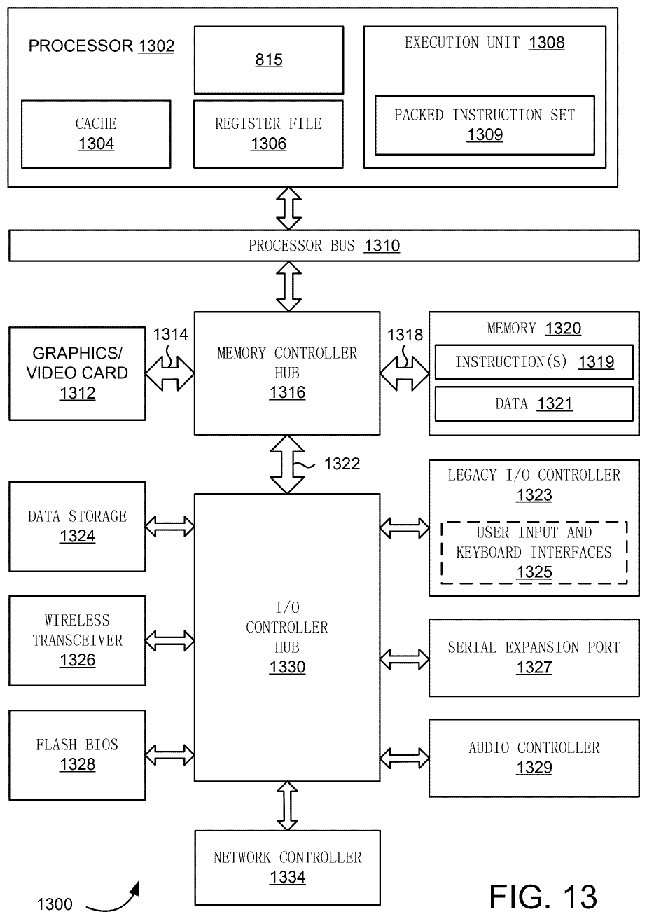

FIG. 13 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 1300 may include, without limitation, a component, such as a processor 1302 to employ execution units including logic to perform algorithms for process data, in accordance with present disclosure, such as in embodiment described herein. In at least one embodiment, computer system 1300 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1300 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 1300 may include, without limitation, processor 1302 that may include, without limitation, one or more execution units 1308 to perform machine learning model training and/or inferencing according to techniques described herein. In at least one embodiment, computer system 1300 is a single processor desktop or server system, but in another embodiment, computer system 1300 may be a multiprocessor system. In at least one embodiment, processor 1302 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 1302 may be coupled to a processor bus 1310 that may transmit data signals between processor 1302 and other components in computer system 1300.

In at least one embodiment, processor 1302 may include, without limitation, a Level 1 (“L1”) internal cache memory (“cache”) 1304. In at least one embodiment, processor 1302 may have a single internal cache or multiple levels of internal cache. In at least one embodiment, cache memory may reside external to processor 1302. Other embodiments may also include a combination of both internal and external caches depending on particular implementation and needs. In at least one embodiment, a register file 1306 may store different types of data in various registers including, without limitation, integer registers, floating point registers, status registers, and an instruction pointer register.

In at least one embodiment, execution unit 1308, including, without limitation, logic to perform integer and floating point operations, also resides in processor 1302. In at least one embodiment, processor 1302 may also include a microcode (“ucode”) read only memory (“ROM”) that stores microcode for certain macro instructions. In at least one embodiment, execution unit 1308 may include logic to handle a packed instruction set 130. In at least one embodiment, by including packed instruction set 1309 in an instruction set of a general-purpose processor, along with associated circuitry to execute instructions, operations used by many multimedia applications may be performed using packed data in processor 1302. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 1308 may also be used in microcontrollers, embedded processors, graphics devices, DSPs, and other types of logic circuits. In at least one embodiment, computer system 1300 may include, without limitation, a memory 1320. In at least one embodiment, memory 1320 may be a Dynamic Random Access Memory (“DRAM”) device, a Static Random Access Memory (“SRAM”) device, a flash memory device, or another memory device. In at least one embodiment, memory 1320 may store instruction(s) 1319 and/or data 1321 represented by data signals that may be executed by processor 1302.

In at least one embodiment, a system logic chip may be coupled to processor bus 1310 and memory 1320. In at least one embodiment, a system logic chip may include, without limitation, a memory controller hub (“MCH”) 1316, and processor 1302 may communicate with MCH 1316 via processor bus 1310. In at least one embodiment, MCH 1316 may provide a high bandwidth memory path 1318 to memory 1320 for instruction and data storage and for storage of graphics commands, data, and textures. In at least one embodiment, MCH 1316 may direct data signals between processor 1302, memory 1320, and other components in computer system 1300 and to bridge data signals between processor bus 1310, memory 1320, and a system I/O interface 1322. In at least one embodiment, a system logic chip may provide a graphics port for coupling to a graphics controller. In at least one embodiment, MCH 1316 may be coupled to memory 1320 through high bandwidth memory path 1318 and a graphics/video card 1312 may be coupled to MCH 1316 through an Accelerated Graphics Port (“AGP”) interconnect 1314.

In at least one embodiment, computer system 1300 may use system I/O interface 1322 as a proprietary hub interface bus to couple MCH 1316 to an I/O controller hub (“ICH”) 1330. In at least one embodiment, ICH 1330 may provide direct connections to some I/O devices via a local I/O bus. In at least one embodiment, a local I/O bus may include, without limitation, a high-speed I/O bus for connecting peripherals to memory 1320, a chipset, and processor 1302. Examples may include, without limitation, an audio controller 1329, a firmware hub (“flash BIOS”) 1328, a wireless transceiver 1326, a data storage 1324, a legacy I/O controller 1323 containing user input and keyboard interfaces 1325, a serial expansion port 1327, such as a Universal Serial Bus (“USB”) port, and a network controller 1334. In at least one embodiment, data storage 1324 may comprise a hard disk drive, a floppy disk drive, a CD-ROM device, a flash memory device, or other mass storage device.

In at least one embodiment, FIG. 13 illustrates a system, which includes interconnected hardware devices or “chips”, whereas in other embodiments, FIG. 13 may illustrate an exemplary SoC. In at least one embodiment, devices illustrated in FIG. 13 may be interconnected with proprietary interconnects, standardized interconnects (e.g., PCIe) or some combination thereof. In at least one embodiment, one or more components of computer system 1300 are interconnected using compute express link (CXL) interconnects.

Inference and/or training logic 815 are used to perform inferencing and/or training operations associated with one or more embodiments. In at least one embodiment, inference and/or training logic 815 may be used in system FIG. 13 for inferencing or predicting operations based, at least in part, on weight parameters calculated using neural network training operations, neural network functions and/or architectures, or neural network use cases described herein.

Embodiments presented herein include cold plates in computer hardware.

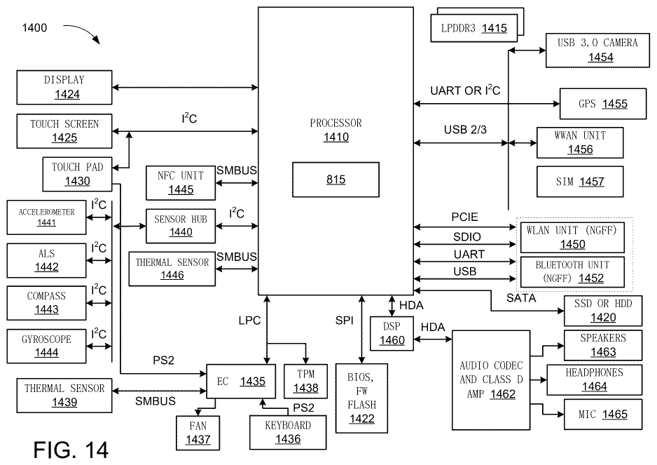

FIG. 14 is a block diagram illustrating an electronic device 1400 for using a processor 1410, according to at least one embodiment. In at least one embodiment, electronic device 1400 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 1400 may include, without limitation, processor 1410 communicatively coupled to any suitable number or kind of components, peripherals, modules, or devices. In at least one embodiment, processor 1410 is coupled using a bus or interface, such as a I²C bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3, etc.), or a Universal Asynchronous Receiver/Transmitter (“UART”) bus. In at least one embodiment, FIG. 14 illustrates a system, which includes interconnected hardware devices or “chips”, whereas in other embodiments, FIG. 14 may illustrate an exemplary SoC. In at least one embodiment, devices illustrated in FIG. 14 may be interconnected with proprietary interconnects, standardized interconnects (e.g., PCIe) or some combination thereof. In at least one embodiment, one or more components of FIG. 14 are interconnected using compute express link (CXL) interconnects.

In at least one embodiment, FIG. 14 may include a display 1424, a touch screen 1425, a touch pad 1430, a Near Field Communications unit (“NFC”) 1445, a sensor hub 1440, a thermal sensor 1446, an Express Chipset (“EC”) 1435, a Trusted Platform Module (“TPM”) 1438, BIOS/firmware/flash memory (“BIOS, FW Flash”) 1422, a DSP 1460, a drive 1420 such as a Solid State Disk (“SSD”) or a Hard Disk Drive (“HDD”), a wireless local area network unit (“WLAN”) 1450, a Bluetooth unit 1452, a Wireless Wide Area Network unit (“WWAN”) 1456, a Global Positioning System (GPS) unit 1455, a camera (“USB 3.0 camera”) 1454 such as a USB 3.0 camera, and/or a Low Power Double Data Rate (“LPDDR”) memory unit (“LPDDR3”) 1415 implemented in, for example, an LPDDR3 standard. These components may each be implemented in any suitable manner.

In at least one embodiment, other components may be communicatively coupled to processor 1410 through components described herein. In at least one embodiment, an accelerometer 1441, an ambient light sensor (“ALS”) 1442, a compass 1443, and a gyroscope 1444 may be communicatively coupled to sensor hub 1440. In at least one embodiment, a thermal sensor 1439, a fan 1437, a keyboard 1436, and touch pad 1430 may be communicatively coupled to EC 1435. In at least one embodiment, speakers 1463, headphones 1464, and a microphone (“mic”) 1465 may be communicatively coupled to an audio unit (“audio codec and class D amp”) 1462, which may in turn be communicatively coupled to DSP 1460. In at least one embodiment, audio unit 1462 may include, for example and without limitation, an audio coder/decoder (“codec”) and a class D amplifier. In at least one embodiment, a SIM card (“SIM”) 1457 may be communicatively coupled to WWAN unit 1456. In at least one embodiment, components such as WLAN unit 1450 and Bluetooth unit 1452, as well as WWAN unit 1456 may be implemented in a Next Generation Form Factor (“NGFF”).

Inference and/or training logic 815 are used to perform inferencing and/or training operations associated with one or more embodiments. In at least one embodiment, inference and/or training logic 815 may be used in system FIG. 14 for inferencing or predicting operations based, at least in part, on weight parameters calculated using neural network training operations, neural network functions and/or architectures, or neural network use cases described herein.

Embodiments presented herein include cold plates in computer hardware.

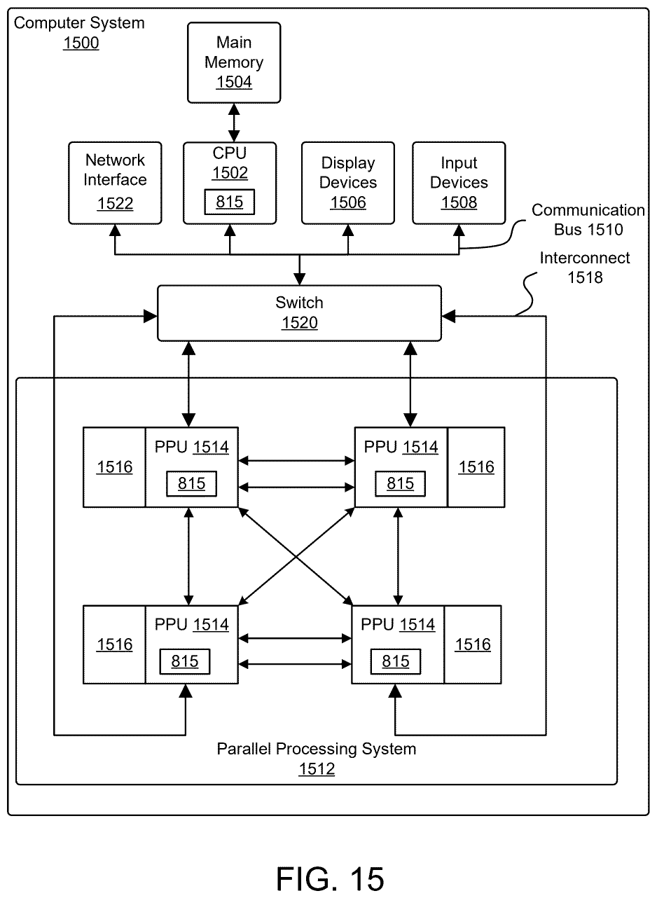

FIG. 15 illustrates a computer system 1500, according to at least one embodiment. In at least one embodiment, computer system 1500 is configured to implement various processes and methods described throughout this disclosure.

In at least one embodiment, computer system 1500 comprises, without limitation, at least one central processing unit (“CPU”) 1502 that is connected to a communication bus 1510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1500 includes, without limitation, a main memory 1504 and control logic (e.g., implemented as hardware, software, or a combination thereof) and data are stored in main memory 1504, which may take form of random access memory (“RAM”). In at least one embodiment, a network interface subsystem (“network interface”) 1522 provides an interface to other computing devices and networks for receiving data from and transmitting data to other systems with computer system 1500.

In at least one embodiment, computer system 1500, in at least one embodiment, includes, without limitation, input devices 1508, a parallel processing system 1512, and display devices 1506 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 1508 such as keyboard, mouse, touchpad, microphone, etc. In at least one embodiment, each module described herein can be situated on a single semiconductor platform to form a processing system.

Inference and/or training logic 815 are used to perform inferencing and/or training operations associated with one or more embodiments. In at least one embodiment, inference and/or training logic 815 may be used in system FIG. 15 for inferencing or predicting operations based, at least in part, on weight parameters calculated using neural network training operations, neural network functions and/or architectures, or neural network use cases described herein.

Embodiments presented herein include cold plates in computer hardware.

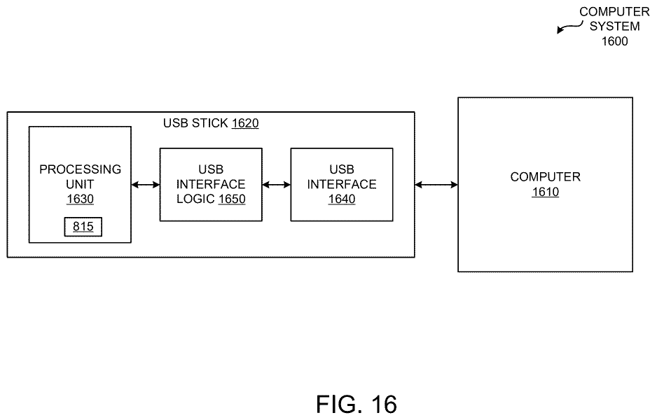

FIG. 16 illustrates a computer system 1600, according to at least one embodiment. In at least one embodiment, computer system 1600 includes, without limitation, a computer 1610 and a USB stick 1620. In at least one embodiment, computer 1610 may include, without limitation, any number and type of processor(s) (not shown) and a memory (not shown). In at least one embodiment, computer 1610 includes, without limitation, a server, a cloud instance, a laptop, and a desktop computer.

In at least one embodiment, USB stick 1620 includes, without limitation, a processing unit 1630, a USB interface 1640, and USB interface logic 1650. In at least one embodiment, processing unit 1630 may be any instruction execution system, apparatus, or device capable of executing instructions. In at least one embodiment, processing unit 1630 may include, without limitation, any number and type of processing cores (not shown). In at least one embodiment, processing unit 1630 comprises an application specific integrated circuit (“ASIC”) that is optimized to perform any amount and type of operations associated with machine learning. For instance, in at least one embodiment, processing unit 1630 is a tensor processing unit (“TPC”) that is optimized to perform machine learning inference operations. In at least one embodiment, processing unit 1630 is a vision processing unit (“VPU”) that is optimized to perform machine vision and machine learning inference operations.

In at least one embodiment, USB interface 1640 may be any type of USB connector or USB socket. For instance, in at least one embodiment, USB interface 1640 is a USB 3.0 Type-C socket for data and power. In at least one embodiment, USB interface 1640 is a USB 3.0 Type-A connector. In at least one embodiment, USB interface logic 1650 may include any amount and type of logic that enables processing unit 1630 to interface with devices (e.g., computer 1610) via USB connector 1640.

Inference and/or training logic 815 are used to perform inferencing and/or training operations associated with one or more embodiments. In at least one embodiment, inference and/or training logic 815 may be used in system FIG. 16 for inferencing or predicting operations based, at least in part, on weight parameters calculated using neural network training operations, neural network functions and/or architectures, or neural network use cases described herein.

Embodiments presented herein include cold plates in computer hardware.

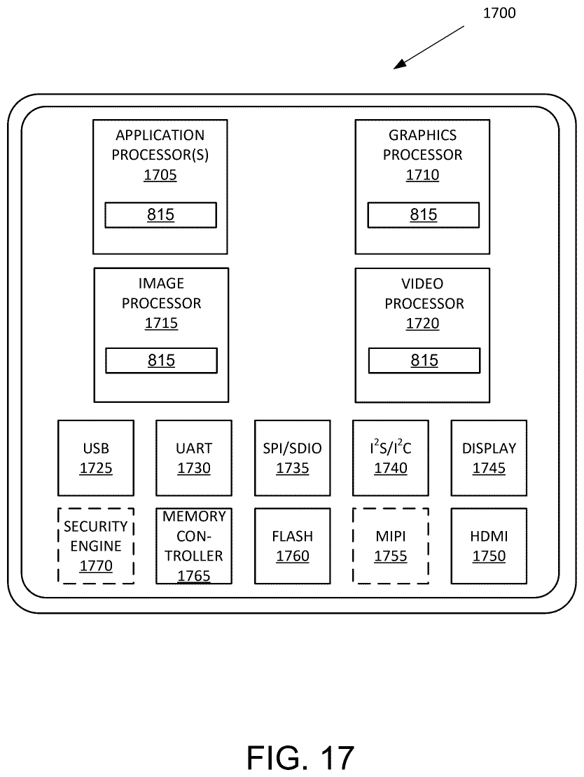

FIG. 17 illustrates exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIG. 17 is a block diagram illustrating an exemplary system-on-a-chip (SOC) integrated circuit 1700 that may be fabricated using one or more IP cores, according to at least one embodiment. In at least one embodiment, SOC integrated circuit 1700 includes one or more application processor(s) 1705 (e.g., CPUs), at least one graphics processor 1710, and may additionally include an image processor 1715 and/or a video processor 1720, any of which may be a modular IP core. In at least one embodiment, SOC integrated circuit 1700 includes peripheral or bus logic including a USB controller 1725, a UART controller 1730, an SPI/SDIO controller 1735, and an I²2S/I²2C controller 1740. In at least one embodiment, SOC integrated circuit 1700 can include a display device 1745 coupled to one or more of a high-definition multimedia interface (HDMI) controller 1750 and a mobile industry processor interface (MIPI) display interface 1755. In at least one embodiment, storage may be provided by a flash memory subsystem 1760 including flash memory and a flash memory controller. In at least one embodiment, a memory interface may be provided via a memory controller 1765 for access to SDRAM or SRAM memory devices. In at least one embodiment, some integrated circuits additionally include an embedded security engine 1770.

Inference and/or training logic 815 are used to perform inferencing and/or training operations associated with one or more embodiments. In at least one embodiment, inference and/or training logic 815 may be used in SOC integrated circuit 1700 for inferencing or predicting operations based, at least in part, on weight parameters calculated using neural network training operations, neural network functions and/or architectures, or neural network use cases described herein.

Embodiments presented herein include cold plates in computer hardware.

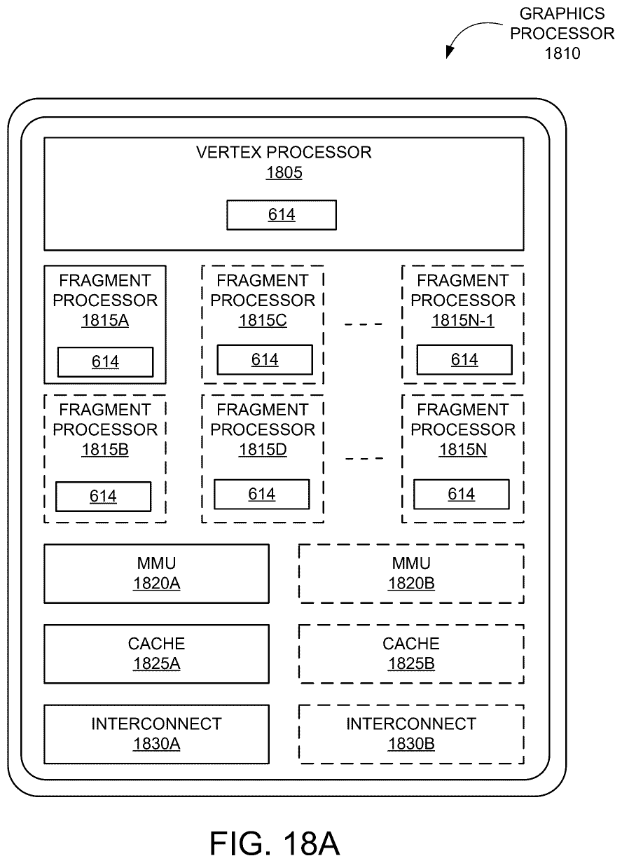

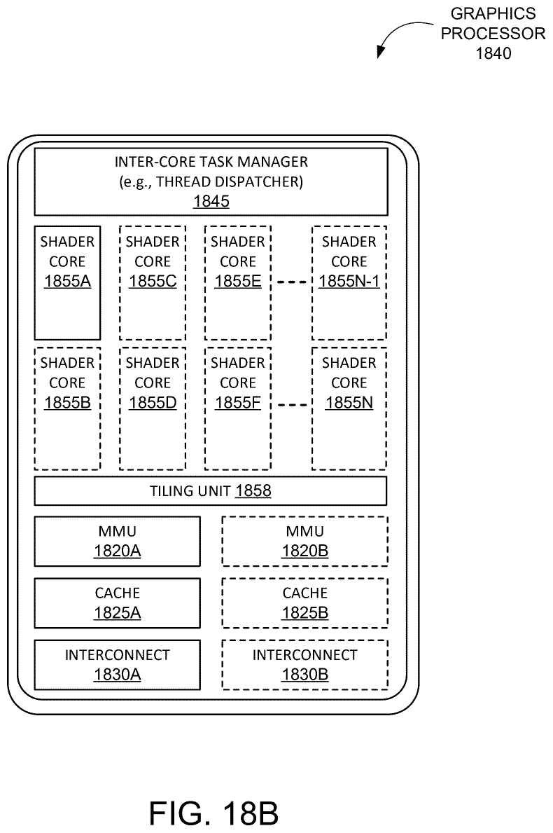

FIGS. 18A-18B illustrate exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIGS. 18A-18B are block diagrams illustrating exemplary graphics processors for use within an SoC, according to embodiments described herein. FIG. 18A illustrates an exemplary graphics processor 1810 of a system on a chip integrated circuit that may be fabricated using one or more IP cores, according to at least one embodiment. FIG. 18B illustrates an additional exemplary graphics processor 1840 of a system on a chip integrated circuit that may be fabricated using one or more IP cores, according to at least one embodiment. In at least one embodiment, graphics processor 1810 of FIG. 18A is a low power graphics processor core. In at least one embodiment, graphics processor 1840 of FIG. 18B is a higher performance graphics processor core. In at least one embodiment, each of graphics processors 1810, 1840 can be variants of computer system 1600 of FIG. 16.

In at least one embodiment, graphics processor 1810 includes a vertex processor 1805 and one or more fragment processor(s) 1815A-1815N (e.g., 1815A, 1815B, 1815C, 1815D, through 1815N-1, and 1815N). In at least one embodiment, graphics processor 1810 can execute different shader programs via separate logic, such that vertex processor 1805 is optimized to execute operations for vertex shader programs, while one or more fragment processor(s) 1815A-1815N execute fragment (e.g., pixel) shading operations for fragment or pixel shader programs. In at least one embodiment, vertex processor 1805 performs a vertex processing stage of a 3D graphics pipeline and generates primitives and vertex data. In at least one embodiment, fragment processor(s) 1815A-1815N use primitive and vertex data generated by vertex processor 1805 to produce a framebuffer that is displayed on a display device. In at least one embodiment, fragment processor(s) 1815A-1815N are optimized to execute fragment shader programs as provided for in an OpenGL API, which may be used to perform similar operations as a pixel shader program as provided for in a Direct 3D API.

In at least one embodiment, graphics processor 1810 additionally includes one or more memory management units (MMUs) 1820A-1820B, cache(s) 1825A-1825B, and circuit interconnect(s) 1830A-1830B. In at least one embodiment, one or more MMU(s) 1820A-1820B provide for virtual to physical address mapping for graphics processor 1810, including for vertex processor 1805 and/or fragment processor(s) 1815A-1815N, which may reference vertex or image/texture data stored in memory, in addition to vertex or image/texture data stored in one or more cache(s) 1825A-1825B. In at least one embodiment, one or more MMU(s) 1820A-1820B may be synchronized with other MMUs within a system, including one or more MMUs associated with one or more application processor(s) 1805, image processors 1815, and/or video processors 1820 of FIG. 18A, such that each processor 1805-1820 can participate in a shared or unified virtual memory system. In at least one embodiment, one or more circuit interconnect(s) 1830A-1830B enable graphics processor 1810 to interface with other IP cores within SoC, either via an internal bus of SoC or via a direct connection.

In at least one embodiment, graphics processor 1840 includes one or more shader core(s) 1855A-1855N (e.g., 1855A, 1855B, 1855C, 1855D, 1855E, 1855F, through 1855N-1, and 1855N) as shown in FIG. 18B, which provides for a unified shader core architecture in which a single core or type or core can execute all types of programmable shader code, including shader program code to implement vertex shaders, fragment shaders, and/or compute shaders. In at least one embodiment, a number of shader cores can vary. In at least one embodiment, graphics processor 1840 includes an inter-core task manager 1845, which acts as a thread dispatcher to dispatch execution threads to one or more shader cores 1855A-1855N and a tiling unit 1858 to accelerate tiling operations for tile-based rendering, in which rendering operations for a scene are subdivided in image space, for example to exploit local spatial coherence within a scene or to optimize use of internal caches.

Embodiments presented herein include cold plates in computer hardware.

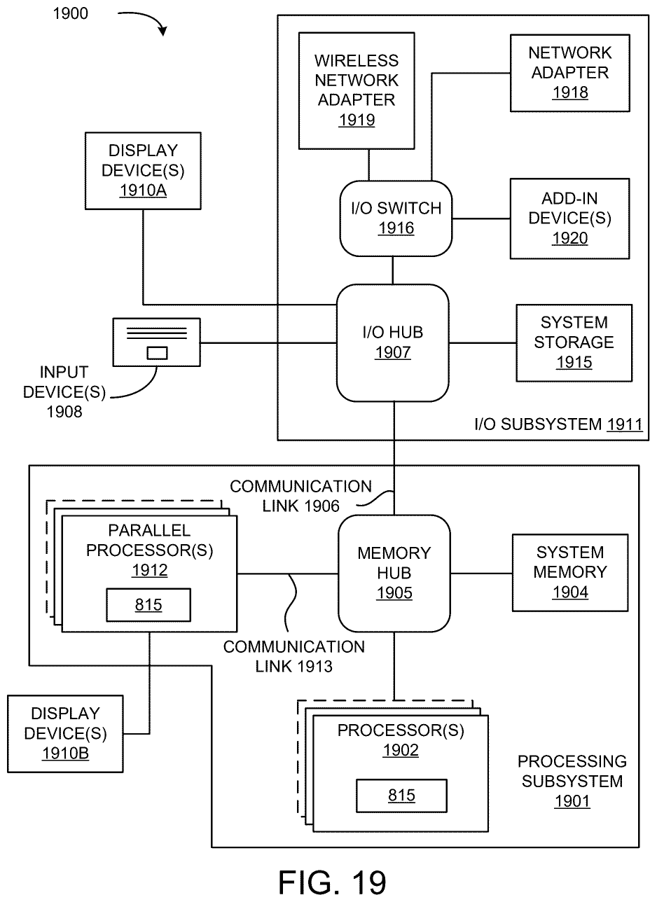

FIG. 19 is a block diagram illustrating a computing system 1900 according to at least one embodiment. In at least one embodiment, computing system 1900 includes a processing subsystem 1901 having one or more processor(s) 1902 and a system memory 1904 communicating via an interconnection path that may include a memory hub 1905. In at least one embodiment, memory hub 1905 may be a separate component within a chipset component or may be integrated within one or more processor(s) 1902. In at least one embodiment, memory hub 1905 couples with an I/O subsystem 1911 via a communication link 1906. In at least one embodiment, I/O subsystem 1911 includes an I/O hub 1907 that can enable computing system 1900 to receive input from one or more input device(s) 1908. In at least one embodiment, I/O hub 1907 can enable a display controller, which may be included in one or more processor(s) 1902, to provide outputs to one or more display device(s) 1910A. In at least one embodiment, one or more display device(s) 1910A coupled with I/O hub 1907 can include a local, internal, or embedded display device.

In at least one embodiment, processing subsystem 1901 includes one or more parallel processor(s) 1912 coupled to memory hub 1905 via a bus or other communication link 1913. In at least one embodiment, communication link 1913 may use one of any number of standards based communication link technologies or protocols, such as but not limited to PCI Express, or may be a vendor-specific communications interface or communications fabric. In at least one embodiment, one or more parallel processor(s) 1912 form a computationally focused parallel or vector processing system that can include a large number of processing cores and/or processing clusters, such as a many-integrated core (MIC) processor. In at least one embodiment, some or all of parallel processor(s) 1912 form a graphics processing subsystem that can output pixels to one of one or more display device(s) 1910A coupled via I/O hub 1907. In at least one embodiment, parallel processor(s) 1912 can also include a display controller and display interface (not shown) to enable a direct connection to one or more display device(s) 1910B. In at least one embodiment, parallel processor(s) 1912 include one or more cores, such as graphics cores 1900 discussed herein.

In at least one embodiment, a system storage unit 1915 can connect to I/O hub 1907 to provide a storage mechanism for computing system 1900. In at least one embodiment, an I/O switch 1916 can be used to provide an interface mechanism to enable connections between I/O hub 1907 and other components, such as a network adapter 1918 and/or a wireless network adapter 1919 that may be integrated into platform, and various other devices that can be added via one or more add-in device(s) 1920. In at least one embodiment, network adapter 1918 can be an Ethernet adapter or another wired network adapter. In at least one embodiment, wireless network adapter 1919 can include one or more of a Wi-Fi, Bluetooth, near field communication (NFC), or other network device that includes one or more wireless radios.

In at least one embodiment, computing system 1900 can include other components not explicitly shown, including USB or other port connections, optical storage drives, video capture devices, and like, may also be connected to I/O hub 1907. In at least one embodiment, communication paths interconnecting various components in FIG. 19 may be implemented using any suitable protocols, such as PCI (Peripheral Component Interconnect) based protocols (e.g., PCI-Express), or other bus or point-to-point communication interfaces and/or protocol(s), such as NV-Link high-speed interconnect, or interconnect protocols.

In at least one embodiment, parallel processor(s) 1912 incorporate circuitry optimized for graphics and video processing, including, for example, video output circuitry, and constitutes a graphics processing unit (GPU), e.g., parallel processor(s) 1912 includes graphics core 1900. In at least one embodiment, parallel processor(s) 1912 incorporate circuitry optimized for general purpose processing. In at least embodiment, components of computing system 1900 may be integrated with one or more other system elements on a single integrated circuit. For example, in at least one embodiment, parallel processor(s) 1912, memory hub 1905, processor(s) 1902, and I/O hub 1907 can be integrated into a system on chip (SoC) integrated circuit. In at least one embodiment, components of computing system 1900 can be integrated into a single package to form a system in package (SIP) configuration. In at least one embodiment, at least a portion of components of computing system 1900 can be integrated into a multi-chip module (MCM), which can be interconnected with other multi-chip modules into a modular computing system.

Inference and/or training logic 815 are used to perform inferencing and/or training operations associated with one or more embodiments. In at least one embodiment, inference and/or training logic 815 may be used in system FIG. 19 for inferencing or predicting operations based, at least in part, on weight parameters calculated using neural network training operations, neural network functions and/or architectures, or neural network use cases described herein.

Embodiments presented herein include cold plates in computer hardware.

### Processors

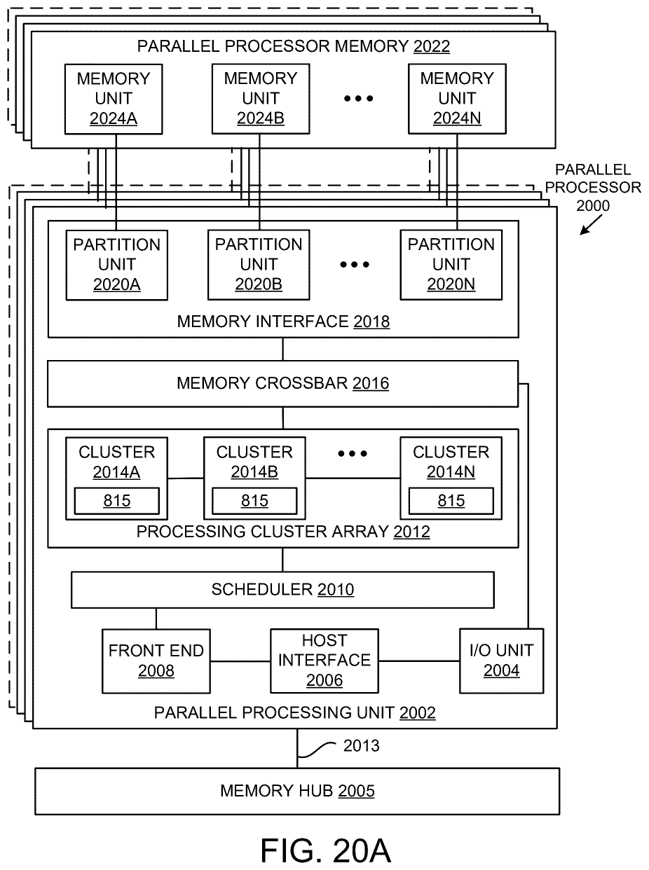

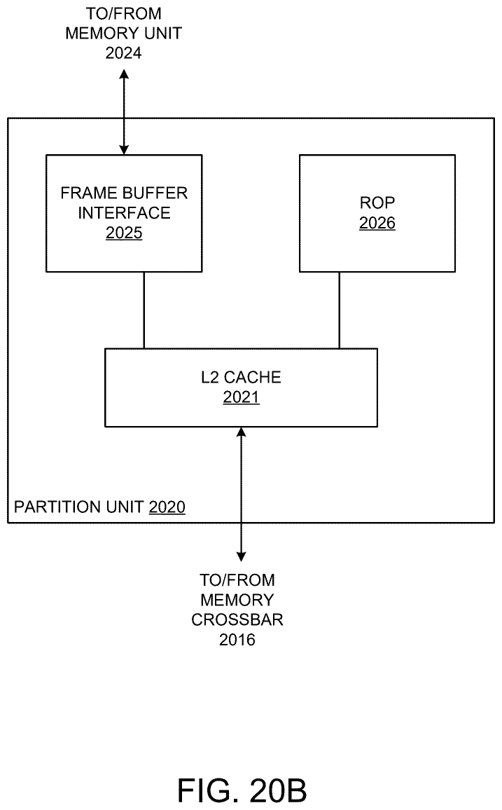

FIG. 20A illustrates a parallel processor 2000 according to at least one embodiment. In at least one embodiment, various components of parallel processor 2000 may be implemented using one or more integrated circuit devices, such as programmable processors, application specific integrated circuits (ASICs), or field programmable gate arrays (FPGA). In at least one embodiment, illustrated parallel processor 2000 is a variant of one or more parallel processor(s) 1912 shown in FIG. 19 according to an exemplary embodiment. In at least one embodiment, a parallel processor 2000 includes one or more graphics cores 1500.

In at least one embodiment, parallel processor 2000 includes a parallel processing unit 2002. In at least one embodiment, parallel processing unit 2002 includes an I/O unit 2004 that enables communication with other devices, including other instances of parallel processing unit 2002. In at least one embodiment, I/O unit 2004 may be directly connected to other devices. In at least one embodiment, I/O unit 2004 connects with other devices via use of a hub or switch interface, such as a memory hub 2005. In at least one embodiment, connections between memory hub 2005 and I/O unit 2004 form a communication link 2013. In at least one embodiment, I/O unit 2004 connects with a host interface 2006 and a memory crossbar 2016, where host interface 2006 receives commands directed to performing processing operations and memory crossbar 2016 receives commands directed to performing memory operations.

In at least one embodiment, when host interface 2006 receives a command buffer via I/O unit 2004, host interface 2006 can direct work operations to perform those commands to a front end 2008. In at least one embodiment, front end 2008 couples with a scheduler 2010 (which may be referred to as a sequencer), which is configured to distribute commands or other work items to a processing cluster array 2012. In at least one embodiment, scheduler 2010 ensures that processing cluster array 2012 is properly configured and in a valid state before tasks are distributed to a cluster of processing cluster array 2012. In at least one embodiment, scheduler 2010 is implemented via firmware logic executing on a microcontroller. In at least one embodiment, microcontroller implemented scheduler 2010 is configurable to perform complex scheduling and work distribution operations at coarse and fine granularity, enabling rapid preemption and context switching of threads executing on processing array 2012. In at least one embodiment, host software can prove workloads for scheduling on processing cluster array 2012 via one of multiple graphics processing paths. In at least one embodiment, workloads can then be automatically distributed across processing array cluster 2012 by scheduler 2010 logic within a microcontroller including scheduler 2010.

In at least one embodiment, processing cluster array 2012 can include up to “N” processing clusters (e.g., cluster 2014A, cluster 2014B, through cluster 2014N), where “N” represents a positive integer (which may be a different integer “N” than used in other figures). In at least one embodiment, each cluster 2014A-2014N of processing cluster array 2012 can execute a large number of concurrent threads. In at least one embodiment, scheduler 2010 can allocate work to clusters 2014A-2014N of processing cluster array 2012 using various scheduling and/or work distribution algorithms, which may vary depending on workload arising for each type of program or computation. In at least one embodiment, scheduling can be handled dynamically by scheduler 2010, or can be assisted in part by compiler logic during compilation of program logic configured for execution by processing cluster array 2012. In at least one embodiment, different clusters 2014A-2014N of processing cluster array 2012 can be allocated for processing different types of programs or for performing different types of computations.

In at least one embodiment, processing cluster array 2012 can be configured to perform various types of parallel processing operations. In at least one embodiment, processing cluster array 2012 is configured to perform general-purpose parallel compute operations. For example, in at least one embodiment, processing cluster array 2012 can include logic to execute processing tasks including filtering of video and/or audio data, performing modeling operations, including physics operations, and performing data transformations.

In at least one embodiment, processing cluster array 2012 is configured to perform parallel graphics processing operations. In at least one embodiment, processing cluster array 2012 can include additional logic to support execution of such graphics processing operations, including but not limited to, texture sampling logic to perform texture operations, as well as tessellation logic and other vertex processing logic. In at least one embodiment, processing cluster array 2012 can be configured to execute graphics processing related shader programs such as but not limited to, vertex shaders, tessellation shaders, geometry shaders, and pixel shaders. In at least one embodiment, parallel processing unit 2002 can transfer data from system memory via I/O unit 2004 for processing. In at least one embodiment, during processing, transferred data can be stored to on-chip memory (e.g., parallel processor memory 2022) during processing, then written back to system memory.

In at least one embodiment, when parallel processing unit 2002 is used to perform graphics processing, scheduler 2010 can be configured to divide a processing workload into approximately equal sized tasks, to better enable distribution of graphics processing operations to multiple clusters 2014A-2014N of processing cluster array 2012. In at least one embodiment, portions of processing cluster array 2012 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 2014A-2014N may be stored in buffers to allow intermediate data to be transmitted between clusters 2014A-2014N for further processing.

In at least one embodiment, processing cluster array 2012 can receive processing tasks to be executed via scheduler 2010, which receives commands defining processing tasks from front end 2008. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 2010 may be configured to fetch indices corresponding to tasks or may receive indices from front end 2008. In at least one embodiment, front end 2008 can be configured to ensure processing cluster array 2012 is configured to a valid state before a workload specified by incoming command buffers (e.g., batch-buffers, push buffers, etc.) is initiated.

In at least one embodiment, each of one or more instances of parallel processing unit 2002 can couple with a parallel processor memory 2022. In at least one embodiment, parallel processor memory 2022 can be accessed via memory crossbar 2016, which can receive memory requests from processing cluster array 2012 as well as I/O unit 2004. In at least one embodiment, memory crossbar 2016 can access parallel processor memory 2022 via a memory interface 2018. In at least one embodiment, memory interface 2018 can include multiple partition units (e.g., partition unit 2020A, partition unit 2020B, through partition unit 2020N) that can each couple to a portion (e.g., memory unit) of parallel processor memory 2022. In at least one embodiment, a number of partition units 2020A-2020N is configured to be equal to a number of memory units, such that a first partition unit 2020A has a corresponding first memory unit 2024A, a second partition unit 2020B has a corresponding memory unit 2024B, and an N-th partition unit 2020N has a corresponding N-th memory unit 2024N. In at least one embodiment, a number of partition units 2020A-2020N may not be equal to a number of memory units.

In at least one embodiment, memory units 2024A-2024N can include various types of memory devices, including dynamic random access memory (DRAM) or graphics random access memory, such as synchronous graphics random access memory (SGRAM), including graphics double data rate (GDDR) memory. In at least one embodiment, memory units 2024A-2024N may also include 3D stacked memory, including but not limited to high bandwidth memory (HBM), HBM2e, or HDM3. In at least one embodiment, render targets, such as frame buffers or texture maps may be stored across memory units 2024A-2024N, allowing partition units 2020A-2020N to write portions of each render target in parallel to efficiently use available bandwidth of parallel processor memory 2022. In at least one embodiment, a local instance of parallel processor memory 2022 may be excluded in favor of a unified memory design that uses system memory in conjunction with local cache memory.

In at least one embodiment, any one of clusters 2014A-2014N of processing cluster array 2012 can process data that will be written to any of memory units 2024A-2024N within parallel processor memory 2022. In at least one embodiment, memory crossbar 20202016 can be configured to transfer an output of each cluster 2014A-2014N to any partition unit 2020A-2020N or to another cluster 2014A-2014N, which can perform additional processing operations on an output. In at least one embodiment, each cluster 2014A-2014N can communicate with memory interface 2018 through memory crossbar 2016 to read from or write to various external memory devices. In at least one embodiment, memory crossbar 2016 has a connection to memory interface 2018 to communicate with I/O unit 2004, as well as a connection to a local instance of parallel processor memory 2022, enabling processing units within different processing clusters 2014A-2014N to communicate with system memory or other memory that is not local to parallel processing unit 2002. In at least one embodiment, memory crossbar 2016 can use virtual channels to separate traffic streams between clusters 2014A-2014N and partition units 2020A-2020N.

In at least one embodiment, multiple instances of parallel processing unit 2002 can be provided on a single add-in card, or multiple add-in cards can be interconnected. In at least one embodiment, different instances of parallel processing unit 2002 can be configured to interoperate even if different instances have different numbers of processing cores, different amounts of local parallel processor memory, and/or other configuration differences. For example, in at least one embodiment, some instances of parallel processing unit 2002 can include higher precision floating point units relative to other instances. In at least one embodiment, systems incorporating one or more instances of parallel processing unit 2002 or parallel processor 2000 can be implemented in a variety of configurations and form factors, including but not limited to desktop, laptop, or handheld personal computers, servers, workstations, game consoles, and/or embedded systems.

FIG. 20B is a block diagram of a partition unit 2020 according to at least one embodiment. In at least one embodiment, partition unit 2020 is an instance of one of partition units 2020A-2020N of FIG. 20A. In at least one embodiment, partition unit 2020 includes an L2 cache 2021, a frame buffer interface 2025, and a ROP 2026 (raster operations unit). In at least one embodiment, L2 cache 2021 is a read/write cache that is configured to perform load and store operations received from memory crossbar 2016 and ROP 2026. In at least one embodiment, read misses and urgent write-back requests are output by L2 cache 2021 to frame buffer interface 2025 for processing. In at least one embodiment, updates can also be sent to a frame buffer via frame buffer interface 2025 for processing. In at least one embodiment, frame buffer interface 2025 interfaces with one of memory units in parallel processor memory, such as memory units 2024A-2024N of FIG. 20A (e.g., within parallel processor memory 2022).

In at least one embodiment, ROP 2026 is a processing unit that performs raster operations such as stencil, z test, blending, etc. In at least one embodiment, ROP 2026 then outputs processed graphics data that is stored in graphics memory. In at least one embodiment, ROP 2026 includes compression logic to compress depth or color data that is written to memory and decompress depth or color data that is read from memory. In at least one embodiment, compression logic can be lossless compression logic that makes use of one or more of multiple compression algorithms. In at least one embodiment, a type of compression that is performed by ROP 2026 can vary based on statistical characteristics of data to be compressed. For example, in at least one embodiment, delta color compression is performed on depth and color data on a per-tile basis.

In at least one embodiment, ROP 2026 is included within each processing cluster (e.g., cluster 2014A-2014N of FIG. 20A) instead of within partition unit 2020. In at least one embodiment, read and write requests for pixel data are transmitted over memory crossbar 2016 instead of pixel fragment data. In at least one embodiment, processed graphics data may be displayed on a display device, such as one of one or more display device(s) 1910 of FIG. 19, routed for further processing by processor(s) 2002, or routed for further processing by one of processing entities within parallel processor 2000 of FIG. 20A.

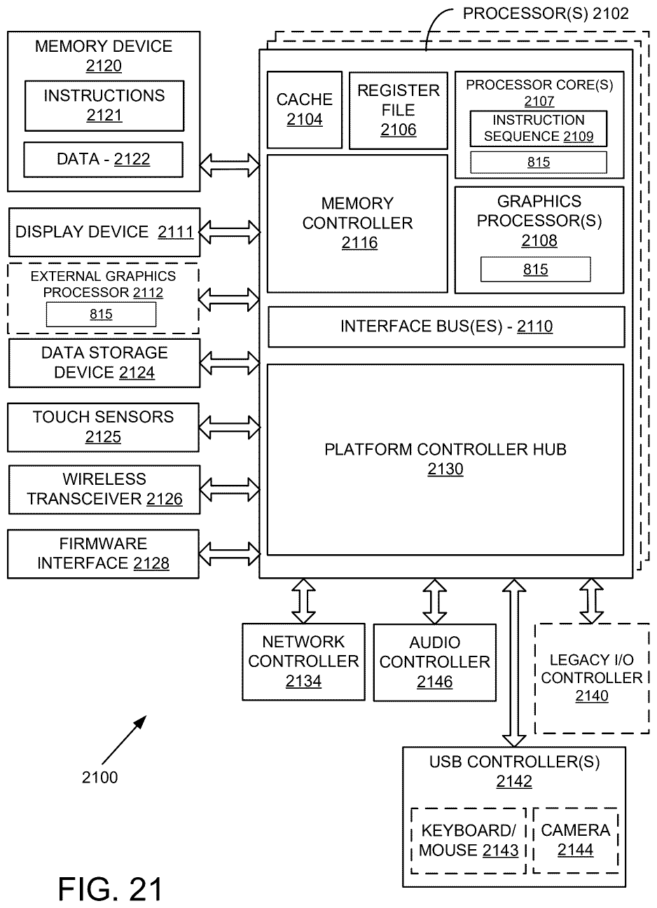

FIG. 21 is a block diagram of a processing system, according to at least one embodiment. In at least one embodiment, system 2100 includes one or more processor(s) 2102 and one or more graphics processor(s) 2108, and may be a single processor desktop system, a multiprocessor workstation system, or a server system having a large number of processor(s) 2102 or processor core(s) 2107. In at least one embodiment, system 2100 is a processing platform incorporated within a system-on-a-chip (SoC) integrated circuit for use in mobile, handheld, or embedded devices. In at least one embodiment, one or more graphics processor(s) 2108 include one or more graphics cores 1500.

In at least one embodiment, system 2100 can include, or be incorporated within a server-based gaming platform, a game console, including a game and media console, a mobile gaming console, a handheld game console, or an online game console. In at least one embodiment, system 2100 is a mobile phone, a smart phone, a tablet computing device or a mobile Internet device. In at least one embodiment, system 2100 can also include, couple with, or be integrated within a wearable device, such as a smart watch wearable device, a smart eyewear device, an augmented reality device, or a virtual reality device. In at least one embodiment, system 2100 is a television or set top box device having one or more processor(s) 2102 and a graphical interface generated by one or more graphics processor(s) 2108.

In at least one embodiment, one or more processor(s) 2102 each include one or more processor core(s) 2107 to process instructions which, when executed, perform operations for system and user software. In at least one embodiment, each of one or more processor core(s) 2107 is configured to process a specific instruction sequence 2109. In at least one embodiment, instruction sequence 2109 may facilitate Complex Instruction Set Computing (CISC), Reduced Instruction Set Computing (RISC), or computing via a Very Long Instruction Word (VLIW). In at least one embodiment, processor core(s) 2107 may each process a different instruction sequence 2109, which may include instructions to facilitate emulation of other instruction sequences. In at least one embodiment, processor core(s) 2107 may also include other processing devices, such a Digital Signal Processor (DSP).

In at least one embodiment, processor(s) 2102 includes a cache memory 2104. In at least one embodiment, processor(s) 2102 can have a single internal cache or multiple levels of internal cache. In at least one embodiment, cache memory is shared among various components of processor(s) 2102. In at least one embodiment, processor(s) 2102 also uses an external cache (e.g., a Level-3 (L3) cache or Last Level Cache (LLC)) (not shown), which may be shared among processor core(s) 2107 using known cache coherency techniques. In at least one embodiment, a register file 2106 is additionally included in processor(s) 2102, which may include different types of registers for storing different types of data (e.g., integer registers, floating point registers, status registers, and an instruction pointer register). In at least one embodiment, register file 2106 may include general-purpose registers or other registers.

In at least one embodiment, one or more processor(s) 2102 are coupled with one or more interface bus(es) 2110 to transmit communication signals such as address, data, or control signals between processor(s) 2102 and other components in system 2100. In at least one embodiment, interface bus(es) 2110 can be a processor bus, such as a version of a Direct Media Interface (DMI) bus. In at least one embodiment, interface bus(es) 2110 is not limited to a DMI bus, and may include one or more Peripheral Component Interconnect buses (e.g., PCI, PCI Express), memory busses, or other types of interface busses. In at least one embodiment processor(s) 2102 include an integrated memory controller 2116 and a platform controller hub 2130. In at least one embodiment, memory controller 2116 facilitates communication between a memory device and other components of system 2100, while platform controller hub (PCH) 2130 provides connections to I/O devices via a local I/O bus.

In at least one embodiment, a memory device 2120 can be a dynamic random access memory (DRAM) device, a static random access memory (SRAM) device, flash memory device, phase-change memory device, or some other memory device having suitable performance to serve as process memory. In at least one embodiment, memory device 2120 can operate as system memory for system 2100, to store data 2122 and instructions 2121 for use when one or more processor(s) 2102 executes an application or process. In at least one embodiment, memory controller 2116 also couples with an optional external graphics processor 2112, which may communicate with one or more graphics processor(s) 2108 in processor(s) 2102 to perform graphics and media operations. In at least one embodiment, a display device 2111 can connect to processor(s) 2102. In at least one embodiment, display device 2111 can include one or more of an internal display device, as in a mobile electronic device or a laptop device, or an external display device attached via a display interface (e.g., DisplayPort, etc.). In at least one embodiment, display device 2111 can include a head mounted display (HMD) such as a stereoscopic display device for use in virtual reality (VR) applications or augmented reality (AR) applications.

In at least one embodiment, platform controller hub 2130 enables peripherals to connect to memory device 2120 and processor(s) 2102 via a high-speed I/O bus. In at least one embodiment, I/O peripherals include, but are not limited to, an audio controller 2146, a network controller 2134, a firmware interface 2128, a wireless transceiver 2126, touch sensors 2125, a data storage device 2124 (e.g., hard disk drive, flash memory, etc.). In at least one embodiment, data storage device 2124 can connect via a storage interface (e.g., SATA) or via a peripheral bus, such as a Peripheral Component Interconnect bus (e.g., PCI, PCI Express). In at least one embodiment, touch sensors 2125 can include touch screen sensors, pressure sensors, or fingerprint sensors. In at least one embodiment, wireless transceiver 2126 can be a Wi-Fi transceiver, a Bluetooth transceiver, or a mobile network transceiver such as a 3G, 4G, or Long Term Evolution (LTE) transceiver. In at least one embodiment, firmware interface 2128 enables communication with system firmware, and can be, for example, a unified extensible firmware interface (UEFI). In at least one embodiment, network controller 2134 can enable a network connection to a wired network. In at least one embodiment, a high-performance network controller (not shown) couples with interface bus(es) 2110. In at least one embodiment, audio controller 2146 is a multi-channel high definition audio controller. In at least one embodiment, system 2100 includes an optional legacy I/O controller 2140 for coupling legacy (e.g., Personal System 2 (PS/2)) devices to system 2100. In at least one embodiment, platform controller hub 2130 can also connect to one or more Universal Serial Bus (USB) controller(s) 2142 connect input devices, such as keyboard and mouse 2143 combinations, a camera 2144, or other USB input devices.

In at least one embodiment, an instance of memory controller 2116 and platform controller hub 2130 may be integrated into a discreet external graphics processor, such as external graphics processor 2112. In at least one embodiment, platform controller hub 2130 and/or memory controller 2116 may be external to one or more processor(s) 2102. For example, in at least one embodiment, system 2100 can include an external memory controller 2116 and platform controller hub 2130, which may be configured as a memory controller hub and peripheral controller hub within a system chipset that is in communication with processor(s) 2102.

Embodiments presented herein include cold plates in computer hardware.

Various embodiments can be described by the following clauses:
1. A liquid-cooled server, comprising:
at least one circuit board;
one or more compute devices positioned on the at least one circuit board; and
one or more cold plates to receive a flow of liquid coolant from an external liquid coolant source and to provide a source of cooling for the one or more compute devices separated from the flow of liquid coolant, the one or more cold plates connectable to further provide the flow of liquid coolant to one or more additional components of the liquid-cooled server.
2. The liquid-cooled server of clause 1, wherein the server receives the flow of liquid coolant from the external liquid coolant source to a first plate of the cold plates without an intervening manifold within a server housing.
3. The liquid-cooled server of clause 1, wherein the one or more cold plates are able to connect to the flow of liquid coolant using a manual connection or a blind mate connection.
4. The liquid-cooled server of clause 1, further comprising:
a manifold separate from the one or more cold plates and configured to provide a flow of liquid coolant to one or more second components on the at least one circuit board.
5. The liquid-cooled server of clause 4, further comprising: one or more sensors to monitor the flow of liquid coolant associated with at least one of the manifold and the one or more second components.
6. The liquid-cooled server of clause 5, wherein the one or more sensors provide monitoring data to a data aggregator.
7. The liquid-cooled server of clause 1, wherein individual cold plates of the one or more cold plates are able to be directly connected to multiple flows of liquid coolant.
8. The liquid-cooled server of clause 1, wherein the one or more cold plates are able to be connected using at least one daisy chain-style connection including a plurality of hoses and connectors.
9. The liquid-cooled server of clause 1, wherein a rate of at least a portion of the flow of liquid coolant is balanced using at least one flow damper associated with the one or more cold plates.
10. The liquid-cooled server of clause 1, wherein the one or more cold plate to limit backflow and crossflow of the flow of liquid coolant to the one or more additional components.
11. A cold plate for a computer system, comprising:
at least one inlet to receive a flow of liquid coolant from a liquid coolant loop associated with a remote source;
an exterior thermal transfer surface to provide a source of cooling from the flow of liquid coolant; and
at least one outlet to distribute the flow of liquid coolant to one or more components of the computer system.
12. The cold plate of clause 11, further comprising:
an interface, including a plurality of connectors, between the at least one inlet and the liquid coolant loop without an intervening manifold within the computer system.
13. The cold plate of clause 11, wherein one or more components may be positioned on the exterior thermal transfer surface to receive the source of cooling.
14. The cold plate of clause 11, further comprising:
at least one additional outlet to provide at least a portion of the flow of liquid coolant to the liquid coolant loop; and
at least one additional inlet to receive at least a portion of the flow of liquid coolant from one or more components.
15. The cold plate of clause 11, further comprising:
a plurality of hoses and connectors to connect the at least one outlet to the one or more components including at least one other cold plate.
16. A method for a liquid-cooled server, comprising:
determining at least one component having a heat generating feature;
providing one or more cold plates to receive a flow of coolant from an external liquid coolant source;
determining at least one additional component to receive the flow of coolant; and
enabling the one or more cold plates to provide a source of cooling to the at least one component and further provide the flow of coolant to the at least one additional component.
17. The method for a liquid-cooled server of clause 16, further comprising:
providing, using an interface, the flow of coolant to the one or more cold plates from the external liquid coolant source.
18. The method for a liquid-cooled server of clause 16, wherein the one or more cold plates are able to connect to the flow of liquid coolant using a manual connection or a blind mate connection.
19. The method for a liquid-cooled server of clause 16, further comprising:
flow rate balancing at least a portion of the flow of coolant within the liquid-cooled server using at least one flow damper associated with the one or more cold plates.
20. The method for a liquid-cooled server of clause 16, further comprising:
limiting backflow and crossflow of the flow of liquid coolant to the at least one additional component.
21. A data center cooling system, comprising:
a data center having a plurality of servers, the individual servers including heat generating devices and fluidly connectable components, the individual servers further including one or more cold plates able to receive a flow of liquid coolant into the individual servers, wherein the one or more cold plates are in thermal connection with at least a subset of the heat generating devices and are able to transfer the flow of cooling fluid with at least a subset of the fluidly connectable components.

In at least one embodiment, a single semiconductor platform may refer to a sole unitary semiconductor-based integrated circuit or chip. In at least one embodiment, multi-chip modules may be used with increased connectivity which simulate on-chip operation, and make substantial improvements over using a conventional central processing unit (“CPU”) and bus implementation. In at least one embodiment, various modules may also be situated separately or in various combinations of semiconductor platforms per desires of user.

In at least one embodiment, referring back to FIG. 15, computer programs in form of machine-readable executable code or computer control logic algorithms are stored in main memory 1504 and/or secondary storage. Computer programs, if executed by one or more processors, enable computer system 1500 to perform various functions in accordance with at least one embodiment. In at least one embodiment, main memory 1504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous FIGS. 1-7 are implemented in context of CPU 1502, parallel processing system 1512, an integrated circuit capable of at least a portion of capabilities of both CPU 1502, parallel processing system 1512, a chipset (e.g., a group of integrated circuits designed to work and sold as a unit for performing related functions, etc.), and/or any suitable combination of integrated circuit(s).

In at least one embodiment, architecture and/or functionality of various previous FIGS. 1-7 are implemented in context of a general computer system, a circuit board system, a game console system dedicated for entertainment purposes, an application-specific system, and more. In at least one embodiment, computer system 1500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

The systems and methods described herein may be used by, without limitation, non-autonomous vehicles or machines, semi-autonomous or autonomous vehicles or machines (e.g., in one or more advanced driver assistance systems (ADAS), one or more in-vehicle infotainment systems, one or more emergency vehicle detection systems), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, generative AI, model training or updating, perception, augmented reality, virtual reality, mixed reality, robotics, security and surveillance, simulation and digital twinning, autonomous or semi-autonomous machine applications, deep learning, environment simulation, data center processing, conversational AI, light transport simulation (e.g., ray-tracing, path tracing, etc.), collaborative content creation for 3D assets, generative AI, cloud computing, and/or any other suitable applications.

Disclosed embodiments may be comprised in a variety of different systems such as automotive systems (e.g., an in-vehicle infotainment system for an autonomous or semi-autonomous machine, a perception system for an autonomous or semi-autonomous machine), systems implemented using a robot, aerial systems, medical systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models—such as large language models (LLMs), systems for performing generative AI operations (e.g., using one or more language models, transformer models, encoder/decoder models, etc.), systems for performing light transport simulation, systems for performing collaborative content creation for 3D assets, systems implemented at least partially using cloud computing resources, and/or other types of systems.

In at least one embodiment, parallel processing system 1512 includes, without limitation, a plurality of parallel processing units (“PPUs”) 1514 and associated memories 1516. In at least one embodiment, PPUs 1514 are connected to a host processor or other peripheral devices via an interconnect 1518 and a switch 1520 or multiplexer. In at least one embodiment, parallel processing system 1512 distributes computational tasks across PPUs 1514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1514, although such shared memory may incur performance penalties relative to use of local memory and registers resident to a PPU 1514. In at least one embodiment, operation of PPUs 1514 is synchronized through use of a command such as _syncthreads( ), wherein all threads in a block (e.g., executed across multiple PPUs 1514) to reach a certain point of execution of code before proceeding.

In at least one embodiment, one or more techniques described herein use a oneAPI programming model. In at least one embodiment, a oneAPI programming model refers to a programming model for interacting with various compute accelerator architectures. In at least one embodiment, oneAPI refers to an application programming interface (API) designed to interact with various compute accelerator architectures. In at least one embodiment, a oneAPI programming model uses a DPC++ programming language. In at least one embodiment, a DPC++ programming language refers to a high-level language for data parallel programming productivity. In at least one embodiment, a DPC++ programming language is based at least in part on C and/or C++ programming languages. In at least one embodiment, a oneAPI programming model is a programming model such as those developed by Intel Corporation of Santa Clara, CA.

In at least one embodiment, oneAPI and/or oneAPI programming model is used to interact with various accelerator, GPU, processor, and/or variations thereof, architectures. In at least one embodiment, oneAPI includes a set of libraries that implement various functionalities. In at least one embodiment, oneAPI includes at least a oneAPI DPC++ library, a oneAPI math kernel library, a oneAPI data analytics library, a oneAPI deep neural network library, a oneAPI collective communications library, a oneAPI threading building blocks library, a oneAPI video processing library, and/or variations thereof.

In at least one embodiment, a oneAPI DPC++ library, also referred to as oneDPL, is a library that implements algorithms and functions to accelerate DPC++ kernel programming. In at least one embodiment, oneDPL implements one or more standard template library (STL) functions. In at least one embodiment, oneDPL implements one or more parallel STL functions. In at least one embodiment, oneDPL provides a set of library classes and functions such as parallel algorithms, iterators, function object classes, range-based API, and/or variations thereof. In at least one embodiment, oneDPL implements one or more classes and/or functions of a C++ standard library. In at least one embodiment, oneDPL implements one or more random number generator functions.

In at least one embodiment, a oneAPI math kernel library, also referred to as oneMKL, is a library that implements various optimized and parallelized routines for various mathematical functions and/or operations. In at least one embodiment, oneMKL implements one or more basic linear algebra subprograms (BLAS) and/or linear algebra package (LAPACK) dense linear algebra routines. In at least one embodiment, oneMKL implements one or more sparse BLAS linear algebra routines. In at least one embodiment, oneMKL implements one or more random number generators (RNGs). In at least one embodiment, oneMKL implements one or more vector mathematics (VM) routines for mathematical operations on vectors. In at least one embodiment, oneMKL implements one or more Fast Fourier Transform (FFT) functions.

In at least one embodiment, a oneAPI data analytics library, also referred to as oneDAL, is a library that implements various data analysis applications and distributed computations. In at least one embodiment, oneDAL implements various algorithms for preprocessing, transformation, analysis, modeling, validation, and decision making for data analytics, in batch, online, and distributed processing modes of computation. In at least one embodiment, oneDAL implements various C++ and/or Java APIs and various connectors to one or more data sources. In at least one embodiment, oneDAL implements DPC++ API extensions to a traditional C++ interface and enables GPU usage for various algorithms.

In at least one embodiment, a oneAPI deep neural network library, also referred to as oneDNN, is a library that implements various deep learning functions. In at least one embodiment, oneDNN implements various neural network, machine learning, and deep learning functions, algorithms, and/or variations thereof.

In at least one embodiment, a oneAPI collective communications library, also referred to as oneCCL, is a library that implements various applications for deep learning and machine learning workloads. In at least one embodiment, oneCCL is built upon lower-level communication middleware, such as message passing interface (MPI) and libfabrics. In at least one embodiment, oneCCL enables a set of deep learning specific optimizations, such as prioritization, persistent operations, out of order executions, and/or variations thereof. In at least one embodiment, oneCCL implements various CPU and GPU functions.

In at least one embodiment, a oneAPI threading building blocks library, also referred to as oneTBB, is a library that implements various parallelized processes for various applications. In at least one embodiment, oneTBB is used for task-based, shared parallel programming on a host. In at least one embodiment, oneTBB implements generic parallel algorithms. In at least one embodiment, oneTBB implements concurrent containers. In at least one embodiment, oneTBB implements a scalable memory allocator. In at least one embodiment, oneTBB implements a work-stealing task scheduler. In at least one embodiment, oneTBB implements low-level synchronization primitives. In at least one embodiment, oneTBB is compiler-independent and usable on various processors, such as GPUs, PPUs, CPUs, and/or variations thereof.

In at least one embodiment, a oneAPI video processing library, also referred to as oneVPL, is a library that is used for accelerating video processing in one or more applications. In at least one embodiment, oneVPL implements various video decoding, encoding, and processing functions. In at least one embodiment, oneVPL implements various functions for media pipelines on CPUs, GPUs, and other accelerators. In at least one embodiment, oneVPL implements device discovery and selection in media centric and video analytics workloads. In at least one embodiment, oneVPL implements API primitives for zero-copy buffer sharing.

In at least one embodiment, a oneAPI programming model uses a DPC++ programming language. In at least one embodiment, a DPC++ programming language is a programming language that includes, without limitation, functionally similar versions of CUDA mechanisms to define device code and distinguish between device code and host code. In at least one embodiment, a DPC++ programming language may include a subset of functionality of a CUDA programming language. In at least one embodiment, one or more CUDA programming model operations are performed using a oneAPI programming model using a DPC++ programming language.

In at least one embodiment, any application programming interface (API) described herein is compiled into one or more instructions, operations, or any other signal by a compiler, interpreter, or other software tool. In at least one embodiment, compilation comprises generating one or more machine-executable instructions, operations, or other signals from source code. In at least one embodiment, an API compiled into one or more instructions, operations, or other signals, when performed, causes one or more processors such as graphics processor 1410, graphics processor 1440, graphics core 1500, parallel processor 1700, graphics processor 1900, or any other logic circuit further described herein to perform one or more computing operations.

It should be noted that, while example embodiments described herein may relate to a CUDA programming model, techniques described herein can be used with any suitable programming model, such HIP, oneAPI, and/or variations thereof.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A liquid-cooled server, comprising:
at least one circuit board;
one or more compute devices positioned on the at least one circuit board; and
one or more cold plates to receive a flow of liquid coolant from an external liquid coolant source and to provide a source of cooling for the one or more compute devices separated from the flow of liquid coolant, the one or more cold plates connectable to further provide the flow of liquid coolant to one or more additional components of the liquid-cooled server.

2. The liquid-cooled server of claim 1, wherein the server receives the flow of liquid coolant from the external liquid coolant source to a first plate of the cold plates without an intervening manifold within a server housing.

3. The liquid-cooled server of claim 1, wherein the one or more cold plates are able to connect to the flow of liquid coolant using a manual connection or a blind mate connection.

4. The liquid-cooled server of claim 1, further comprising:
a manifold separate from the one or more cold plates and configured to provide a flow of liquid coolant to one or more second components on the at least one circuit board.

5. The liquid-cooled server of claim 4, further comprising:
one or more sensors to monitor the flow of liquid coolant associated with at least one of the manifold and the one or more second components.

6. The liquid-cooled server of claim 5, wherein the one or more sensors provide monitoring data to a data aggregator.

7. The liquid-cooled server of claim 1, wherein individual cold plates of the one or more cold plates are able to be directly connected to multiple flows of liquid coolant.

8. The liquid-cooled server of claim 1, wherein the one or more cold plates are able to be connected using at least one daisy chain-style connection including a plurality of hoses and connectors.

9. The liquid-cooled server of claim 1, wherein a rate of at least a portion of the flow of liquid coolant is balanced using at least one flow damper associated with the one or more cold plates.

10. The liquid-cooled server of claim 1, wherein the one or more cold plate to limit backflow and crossflow of the flow of liquid coolant to the one or more additional components.

11. A cold plate for a computer system, comprising:
at least one inlet to receive a flow of liquid coolant from a liquid coolant loop associated with a remote source;
an exterior thermal transfer surface to provide a source of cooling from the flow of liquid coolant; and
at least one outlet to distribute the flow of liquid coolant to one or more components of the computer system.

12. The cold plate of claim 11, further comprising:
an interface, including a plurality of connectors, between the at least one inlet and the liquid coolant loop without an intervening manifold within the computer system.

13. The cold plate of claim 11, wherein one or more components may be positioned on the exterior thermal transfer surface to receive the source of cooling.

14. The cold plate of claim 11, further comprising:
at least one additional outlet to provide at least a portion of the flow of liquid coolant to the liquid coolant loop; and
at least one additional inlet to receive at least a portion of the flow of liquid coolant from one or more components.

15. The cold plate of claim 11, further comprising:
a plurality of hoses and connectors to connect the at least one outlet to the one or more components including at least one other cold plate.

16. A method for a liquid-cooled server, comprising:
determining at least one component having a heat generating feature;
providing one or more cold plates to receive a flow of coolant from an external liquid coolant source;
determining at least one additional component to receive the flow of coolant; and
enabling the one or more cold plates to provide a source of cooling to the at least one component and further provide the flow of coolant to the at least one additional component.

17. The method for a liquid-cooled server of claim 16, further comprising:
providing, using an interface, the flow of coolant to the one or more cold plates from the external liquid coolant source.

18. The method for a liquid-cooled server of claim 16, wherein the one or more cold plates are able to connect to the flow of liquid coolant using a manual connection or a blind mate connection.

19. The method for a liquid-cooled server of claim 16, further comprising:
flow rate balancing at least a portion of the flow of coolant within the liquid-cooled server using at least one flow damper associated with the one or more cold plates.

20. The method for a liquid-cooled server of claim 16, further comprising:
limiting backflow and crossflow of the flow of liquid coolant to the at least one additional component.

21. A data center cooling system, comprising:
a data center having a plurality of servers, the individual servers including heat generating devices and fluidly connectable components, the individual servers further including one or more cold plates able to receive a flow of liquid coolant into the individual servers, wherein the one or more cold plates are in thermal connection with at least a subset of the heat generating devices and are able to transfer the flow of cooling fluid with at least a subset of the fluidly connectable components.
